(19) United States
(12) Patent Application Publication
(10) Pub. No.: US 2010/0083898 A1
(43) Pub. Date: Apr. 8, 2010

(54) Substrate processing apparatus

(75) Inventors: Shintaro Kogura, Toyama-shi (JP); Yuji Takebayashi, Toyama-shi (JP); Atsuhiko Ashitani, Toyama-shi (JP); Satoshi Okada, Toyama-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., Tokyo (JP)

(21) Appl. No.: 12/458,816

(22) Filed: Jul. 23, 2009

(30) Foreign Application Priority Data
Jul. 23, 2008 (JP) 2008-190241
Jun. 3, 2009 (JP) 2009-134148

(51) Int. Cl. C23C 16/52; C23C 16/00

(52) U.S. Cl. 118/692; 118/715

(57) ABSTRACT

There are provided an inner tube in which a substrate is stored; an outer tube surrounding the inner tube; a gas nozzle disposed in the inner tube; a gas ejection hole opened on the gas nozzle; a gas supply unit supplying gas into the inner tube through the gas nozzle; a gas exhausts hole opened on the side wall of the inner tube; and an exhaust unit exhausting a space between the outer tube and the inner tube and generating a gas flow in the inner tube toward the gas exhaust hole from the gas ejection hole, wherein the side wall of the inner tube is constituted, so that a distance between an outer edge of the substrate and the gas exhaust hole is set to be longer than a distance between the outer edge of the substrate and the gas ejection hole.

### BACKGROUND

1. Technical Field

The present invention relates to a substrate processing apparatus for processing a substrate.

2. Description of Related Art

Conventionally, a substrate processing step for forming a thin film on a substrate has been executed, as one step of manufacturing steps of a semiconductor device such as DRAM. The substrate processing step has been executed by a substrate processing apparatus including: an inner tube in which a substrate is stored; an outer tube surrounding the inner tube; a gas supply unit supplying gas into the inner tube; and an exhaust unit generating a gas flow in the inner tube by exhausting a space between the outer tube and the inner tube. Then, the thin film has been formed on the substrate, by supplying the gas to the substrate from a horizontal direction.

However, when a conventional substrate processing apparatus is used, a film thickness of the formed thin film becomes thick at an outer edge part of the substrate, and becomes thin in a center part of the substrate, in some cases.

An object of the present invention is to provide a substrate processing apparatus capable of improving a uniformity of a film thickness of a thin film formed on a substrate.

### SUMMARY OF THE INVENTION

According to an aspect of the present invention, there is provided a substrate processing apparatus, including:

an inner tube in which a substrate is stored;

an outer tube surrounding the inner tube;

a gas nozzle disposed in the inner tube;

a gas ejection hole opened on the gas nozzle;

a gas supply unit supplying gas into the inner tube through the gas nozzle;

one or more exhaust holes opened on a side wall of the inner tube; and

an exhaust unit exhausting a space between the outer tube and the inner tube, and generating a gas flow in the inner tube toward the gas exhaust hole from the gas ejection hole,

wherein the side wall of the inner tube is constituted so that a distance between an outer edge of the substrate and the gas exhaust hole is set to be longer than a distance between the outer edge of the substrate and the gas ejection hole.

According to other aspect of the present invention, there is provided a substrate processing apparatus, including:

an inner tube in which a substrate is stored;

an outer tube surrounding the inner tube;

a plurality of a gas nozzle disposed in the inner tube;

gas ejection holes opened on the plurality of gas nozzles respectively;

a gas supply unit supplying gas into the inner tube through the plurality of gas nozzles;

a gas exhaust part provided on a side wall of the inner tube, at positions facing the plurality of gas nozzles across the substrates;

one or more gas exhaust holes opened on the side wall of the gas exhaust part; and

an exhaust unit exhausting a space between the outer tube and the inner tube, and generating a gas flow in the inner tube toward the gas exhaust hole from the gas ejection hole,

wherein the side wall of the inner tube is constituted so that a distance between an outer edge of the substrate and the gas exhaust hole is set to be longer than a distance between the outer edge of the substrate and the gas ejection hole.

According to other aspect of the present invention, there is provided a substrate processing apparatus, including:

an inner tube in which a plurality of substrates are stored in a state of being stacked in a horizontal posture;

an outer tube surrounding the inner tube;

a first gas nozzle and a second gas nozzle disposed respectively along a direction of stacking the substrates in the inner tube;

a plurality of gas ejection holes opened respectively on the first gas nozzle and the second gas nozzle, along the direction of stacking the substrates;

a gas supply unit supplying a first source gas into the inner tube through the first gas nozzle and supplying a second source gas into the inner tube through the second gas nozzle;

one or more exhaust holes opened on a side wall of the inner tube, at positions facing the gas ejection holes across the substrates;

an exhaust unit exhausting a space between the outer tube and the inner tube, and generating a gas flow in the inner tube toward the gas exhaust hole from the gas ejection hole; and

a controller controlling the gas supply unit and the exhaust unit so as to alternately supply at least two kinds of gases into the inner tube without mixing them with each other,

wherein the side wall of the inner tube is constituted, so that a distance between an outer edge of the substrate and the gas exhaust hole is set to be longer than a distance between the outer edge of the substrate and the gas ejection hole.

According to the substrate processing apparatus of the present invention, uniformity in the film thickness of the thin film formed on the substrate can be improved.

### BRIEF DESCRIPTION OF THE DRAWINGS

FIG. 1 is a schematic block diagram of a substrate processing apparatus according to an embodiment of the present invention.

FIG. 2 is a vertical sectional view of a processing furnace provided in the substrate processing apparatus according to an embodiment of the present invention.

FIG. 3 is a perspective view of an inner tube provided in the substrate processing apparatus according to an embodiment of the present invention, showing a case that a gas exhaust hole has a hole shape.

FIG. 4 is a perspective view of the inner tube provided in the substrate processing apparatus according to other embodiment of the present invention, showing a case that one or more gas exhaust holes are formed into a slit shape.

FIG. 5 is a horizontal sectional view of a process tube provided in the substrate processing apparatus according to an embodiment of the present invention, showing a case that a preliminary chamber is provided in the inner tube.

FIG. 6 is a horizontal sectional view of the process tube provided in the substrate processing apparatus according to other embodiment of the present invention, showing a case that the preliminary chamber is not provided in the inner tube.

FIG. 7 is a flow chart of a substrate processing step according to an embodiment of the present invention.

FIG. 8 is a sequence view of a gas supply in the substrate processing step according to an embodiment of the present invention.

FIG. 9 is a table chart exemplifying processing conditions of the substrate processing step according to an embodiment of the present invention.

FIG. 10 is a graph chart showing measurement results of a film thickness distribution of a thin film formed on a wafer, wherein symbol ◯ shows example 1, and symbol ▪ shows comparative example 1, respectively.

FIG. 11 is a schematic view showing the film thickness distribution of the thin film formed on the wafer by a contour line, wherein FIG. 11A shows example 1 of the present invention, FIG. 11B shows example 2 of the present invention, FIG. 11C shows comparative example 1, and FIG. 11D shows comparative example 2, respectively.

FIG. 12 is a schematic view showing simulation conditions of a gas flow velocity distribution in the inner tube.

FIG. 13A shows a simulation result of the gas flow velocity distribution in the inner tube when a distance between an outer edge of a wafer and gas exhaust holes is se to be shorter, and FIG. 13B shows a simulation result of the gas flow velocity distribution in the inner tube when the distance between the outer edge of the wafer and the gas exhaust holes is set to be longer.

FIG. 14 is a schematic view exemplifying a gas flow generated in the process tube provided in the substrate processing apparatus according to an embodiment of the present invention.

FIG. 15 is a horizontal sectional view of a processing furnace provided in a conventional substrate processing apparatus.

FIG. 16 is a side view of the inner tube provided in the substrate processing apparatus according to other embodiment of the present invention.

FIG. 17 is a perspective view showing a modified example of the inner tube provided in the substrate processing apparatus according to an embodiment of the present invention.

### DESCRIPTION OF PREFERRED EMBODIMENTS OF THE INVENTION

As described above, when a conventional substrate processing apparatus is used, a film thickness of a formed thin film becomes thick at an outer edge part of a substrate and becomes thin in a center part of the substrate.

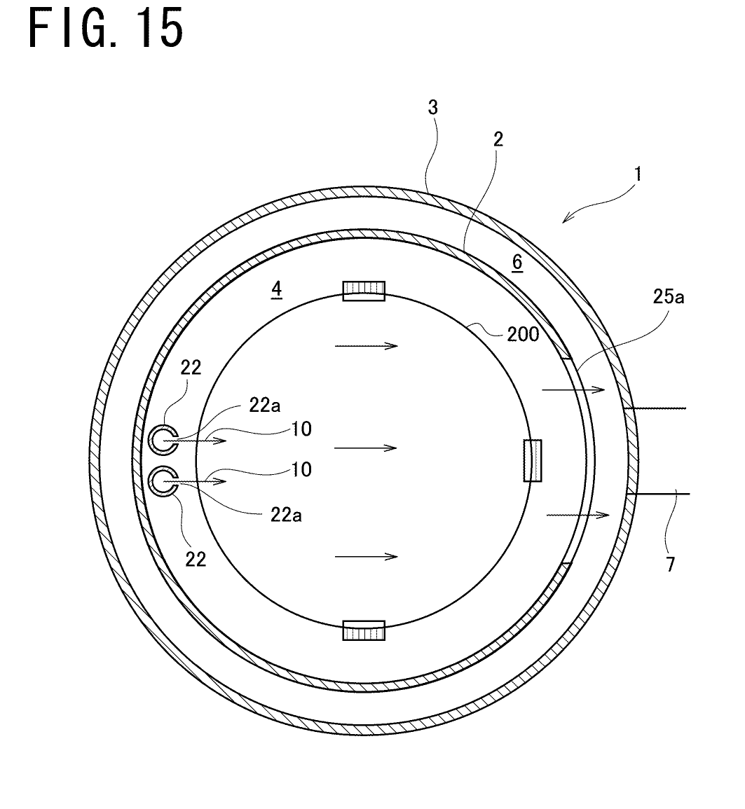

FIG. 15 is a horizontal sectional view of a processing furnace 1 provided in a conventional substrate processing apparatus. The processing furnace 1 includes an inner tube 2 in which wafers 200, being substrates, are stored; an outer tube 3 surrounding the inner tube 2; a pair of gas nozzles 22 disposed in the inner tube 2; gas ejection holes 22a opened on a pair of gas nozzles 22 respectively; gas exhaust holes 25a opened on aside wall of the inner tube 2 and at positions facing the gas ejection holes 22a across the wafers 200; and an exhaust unit 7 exhausting a space between the outer tube 3 and the inner tube 2. Then, gas is supplied into the inner tube 2 from the gas ejection holes 22a, while rotating the wafer 200 in a horizontal posture, and a space between the outer tube 3 and the inner tube 2 is exhausted by the exhaust unit 7 and a gas flow 10 is generated in the inner tube 2 toward the gas exhaust holes 25a from the gas ejection holes 22a, to thereby supply gas to the wafer 200 in a horizontal direction and form a thin film (side flow/side vent system).

Regarding a factor of deteriorating a uniformity of the film thickness, as a result of strenuous efforts and study by inventors of the present invention, it is possible to obtain a knowledge that in the conventional substrate processing apparatus, a gas flow velocity around the gas exhaust hole is more increased than a gas flow velocity in the surface of the wafer, thus inviting a state that an area, where the gas flow velocity is increased, covers the surface of the wafer, or excessively close to the wafer, and such a state is one of the factors of deterioration the uniformity of the film thickness. Further, the inventors of the present invention obtains a knowledge that by more prolonging the distance between the outer edge of the wafer and the gas exhaust hole than conventional, the area, where the gas flow velocity is increased, can be distanced from the wafer, then the gas flow velocity on the wafer can be uniformized, and the uniformity of the film thickness can be improved.

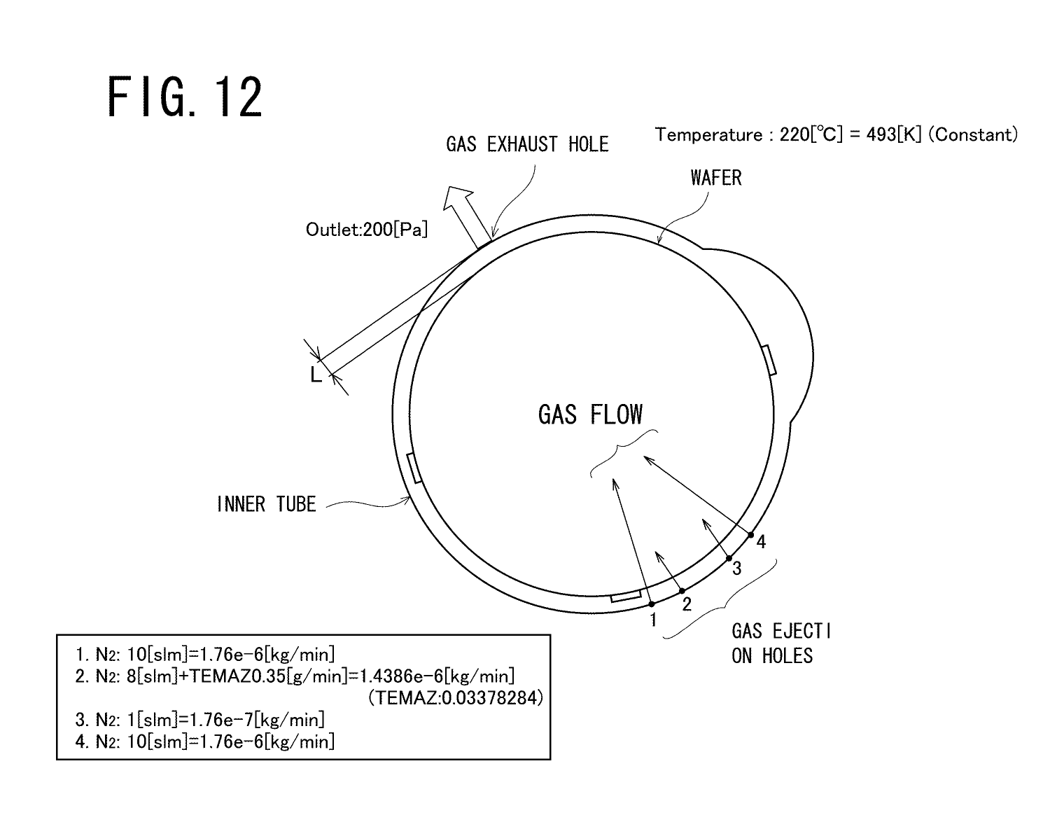

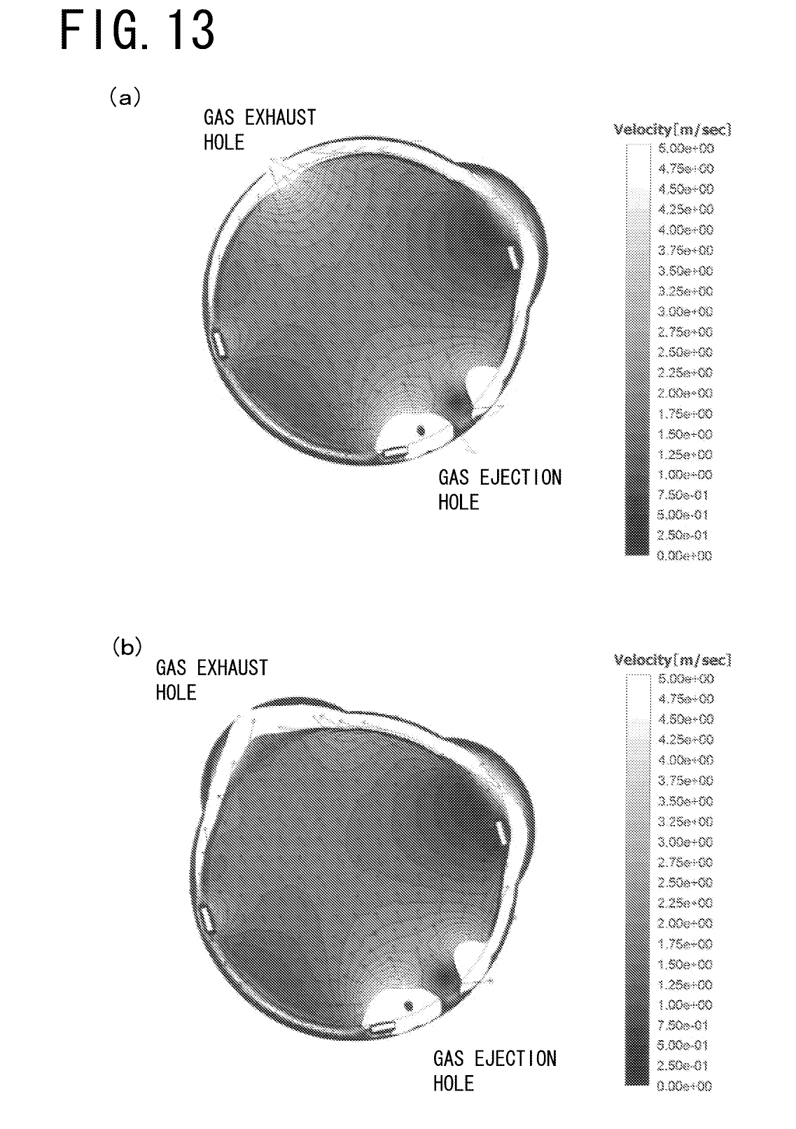

Simulation results regarding a gas flow velocity distribution in the inner tube performed by the inventors of the present invention will be described, with reference to FIG. 12 and FIG. 13.

FIG. 12 is a schematic view showing simulation conditions of the gas flow velocity distribution in the inner tube. In this simulation, from the gas ejection holes at four places disposed on one end in the inner tube (shown by 1 to 4 in the figure), mixed gas of nitrogen (N₂) gas (10 slm), N₂ gas (8 slm), TEMAZr gas (0.35 g/min) obtained by vaporizing TEMAZr (Tetrakis Ethyl Methyl Amino Zirconium), N₂ gas (1 slm), and N₂ gas (10 slm) are respectively supplied. Then, an atmosphere in the inner tube is exhausted from the gas exhaust holes formed at other end of the inner tube, at positions facing the gas ejection holes across the wafer. Note that a pressure outside (outlet) of the inner tube is set to be 200 Pa, and a temperature inside of the inner tube is set to be 220° C. Then, in this simulation, by varying distance L between the outer edge of the wafer stored in the inner tube and the gas exhaust hole, the gas flow velocity distribution in the inner tube is calculated.

FIG. 13A shows the simulation results of the gas flow velocity distribution in the inner tube, when the distance between the outer edge of the wafer and the gas exhaust hole is shortened, and FIG. 13B shows the simulation results of the gas flow velocity distribution in the inner tube when the distance between the outer edge of the wafer and the gas exhaust hole is lengthened. In both of the FIG. 13A and FIG. 13B, the wafer 200 is not rotated. In FIG. 13A, it is found that the area around the gas exhaust hole where the gas flow velocity is increased, covers the surface of the wafer. According to the knowledge of the inventors of the present invention, in such a case, flow rate and concentration of the gas in the surface of the wafer becomes non-uniform, which seems to be a factor of deteriorating the uniformity of the film thickness. Meanwhile, in FIG. 13B, it is found that by securing the distance long between the outer edge of the wafer and the gas exhaust hole, the area, where the gas flow velocity is increased, can be distanced from the wafer and the gas flow velocity on the wafer can be uniformized. Namely, by securing the distance long between the outer edge of the wafer and the gas exhaust hole, the flow rate and the concentration of the gas in the surface of the wafer can be uniformized and the uniformity of the film thickness can be improved. The present invention is provided based on such a knowledge obtained by the inventors of the present invention.

### An Embodiment of the Present Invention

An embodiment of the present invention will be described hereinafter, with reference to the drawings.

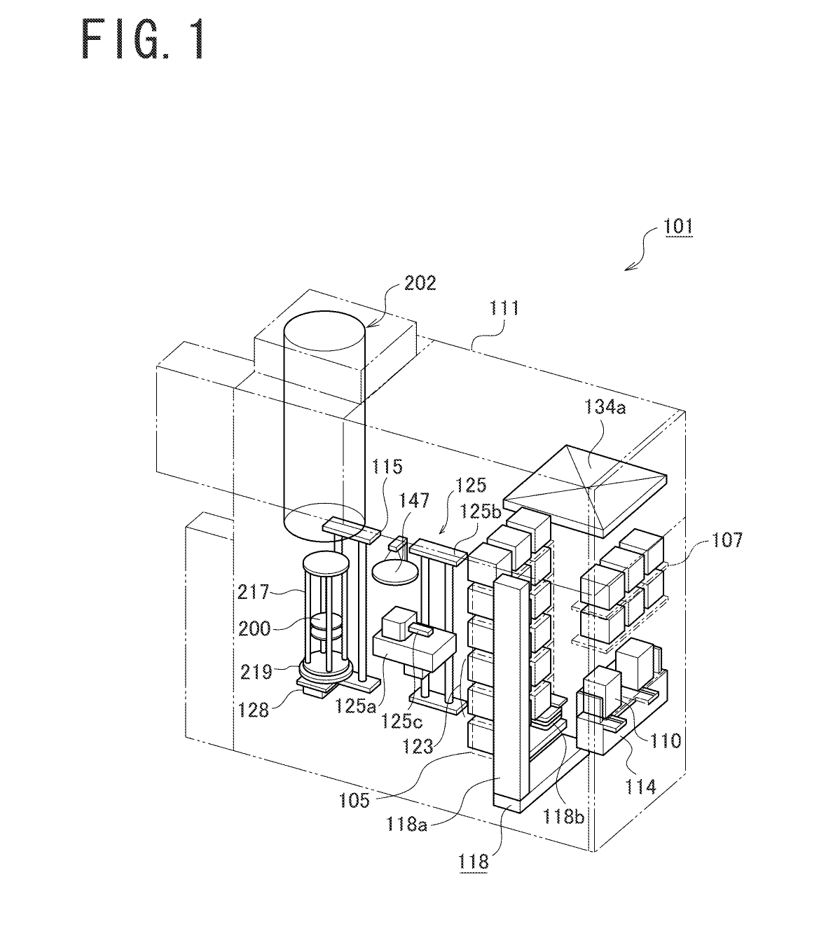

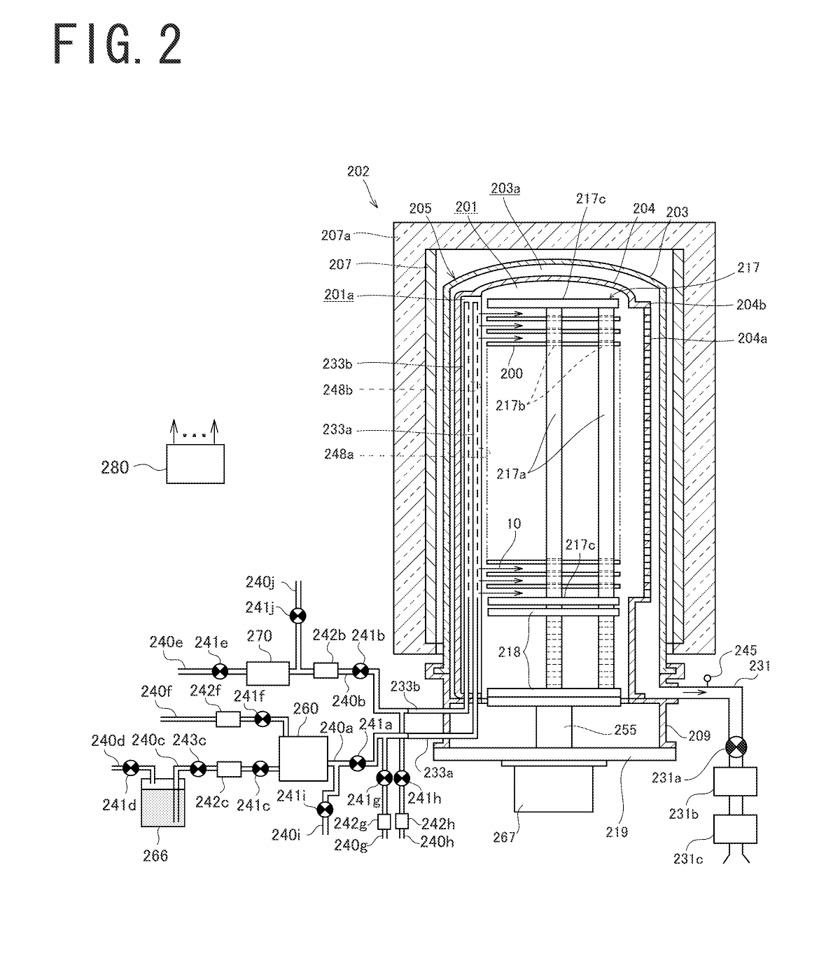

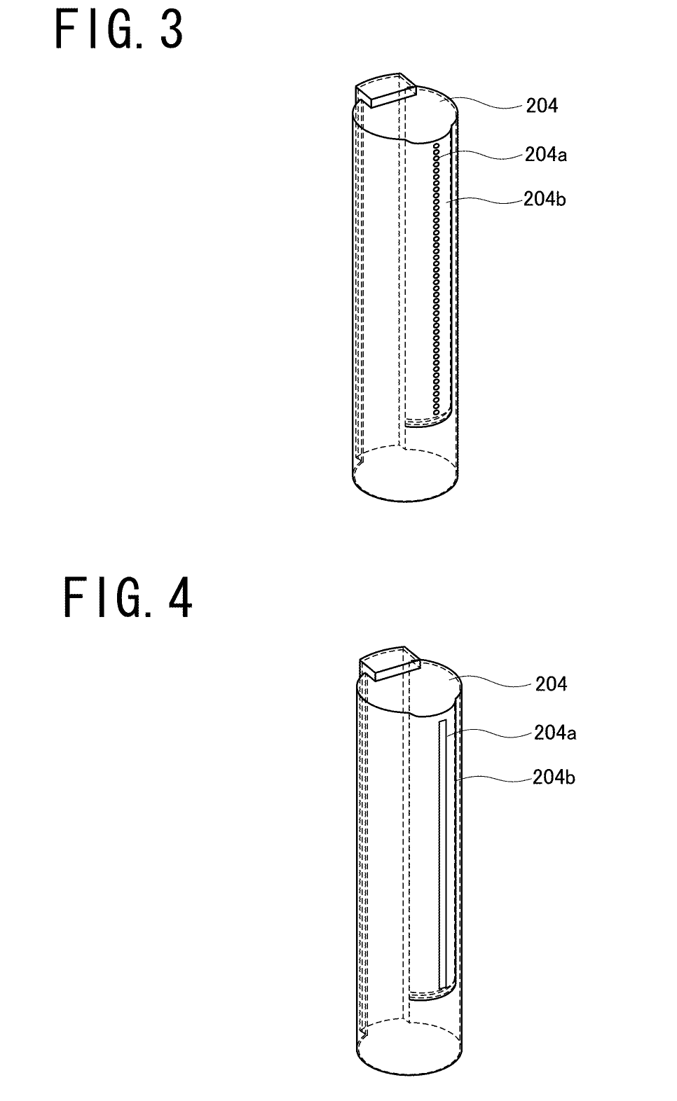

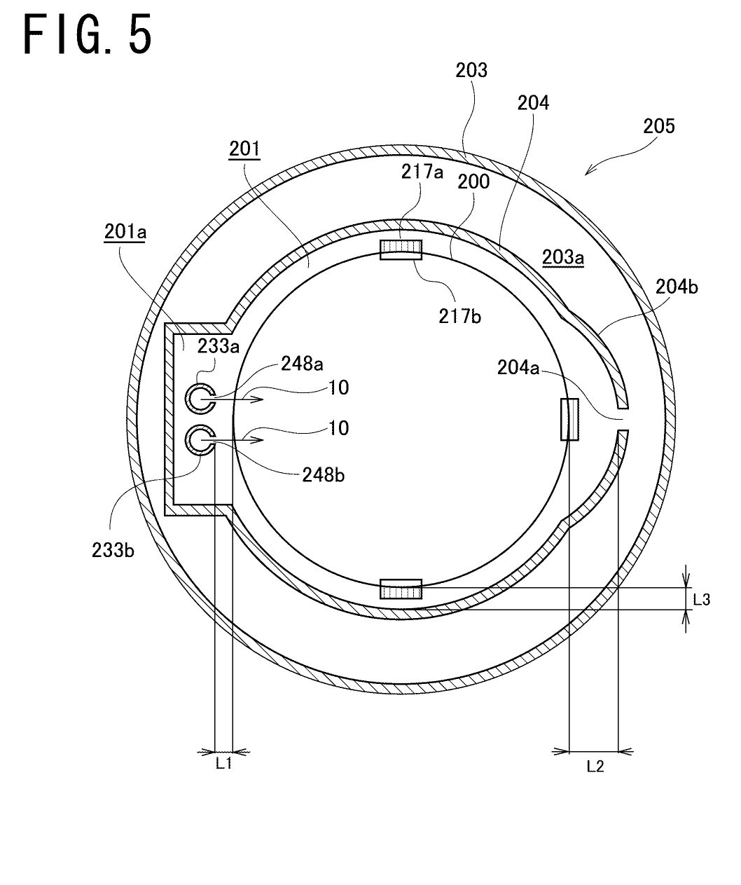

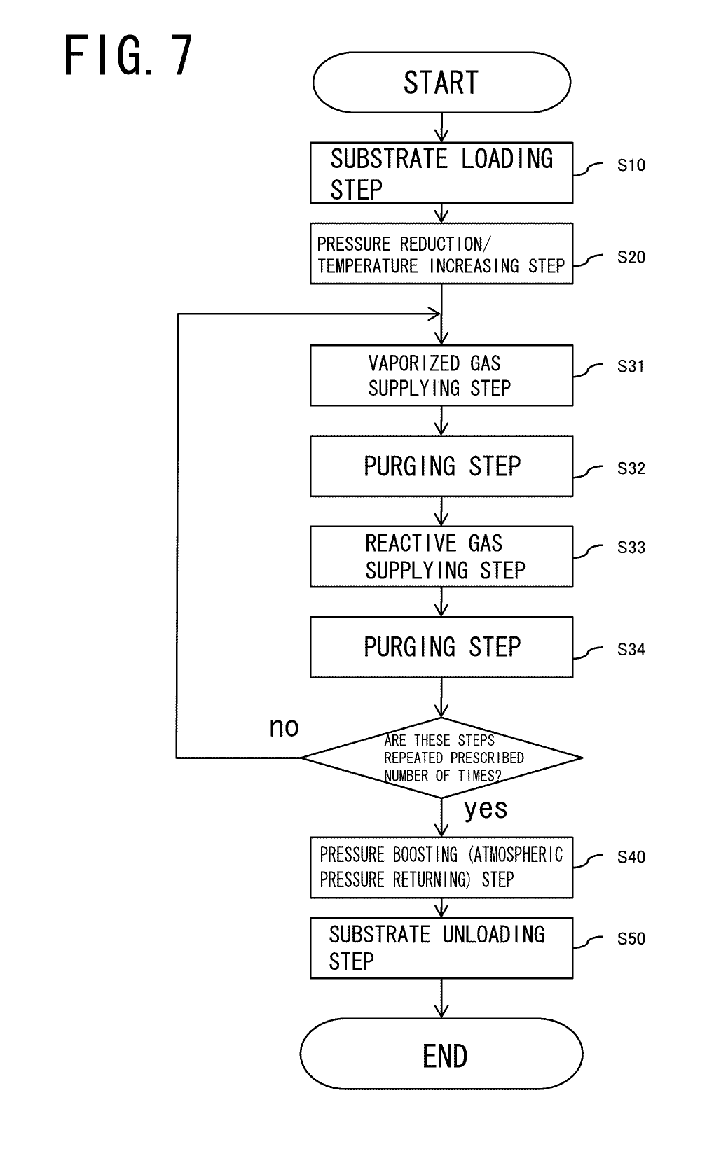

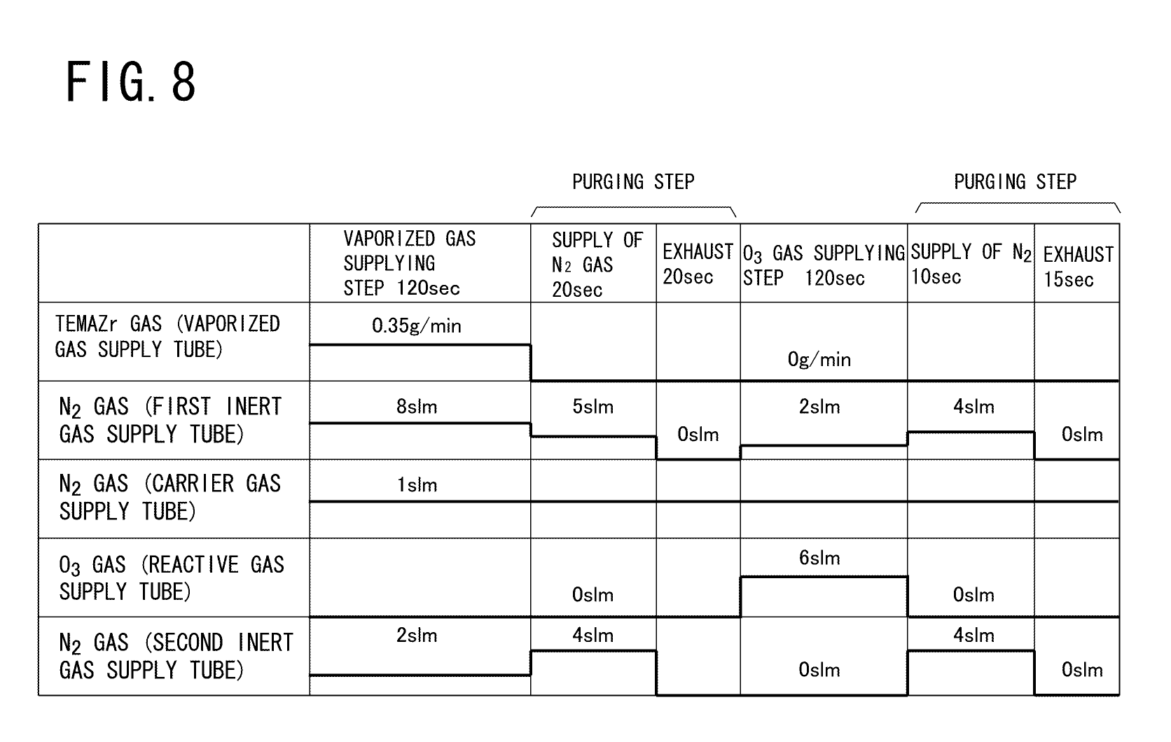

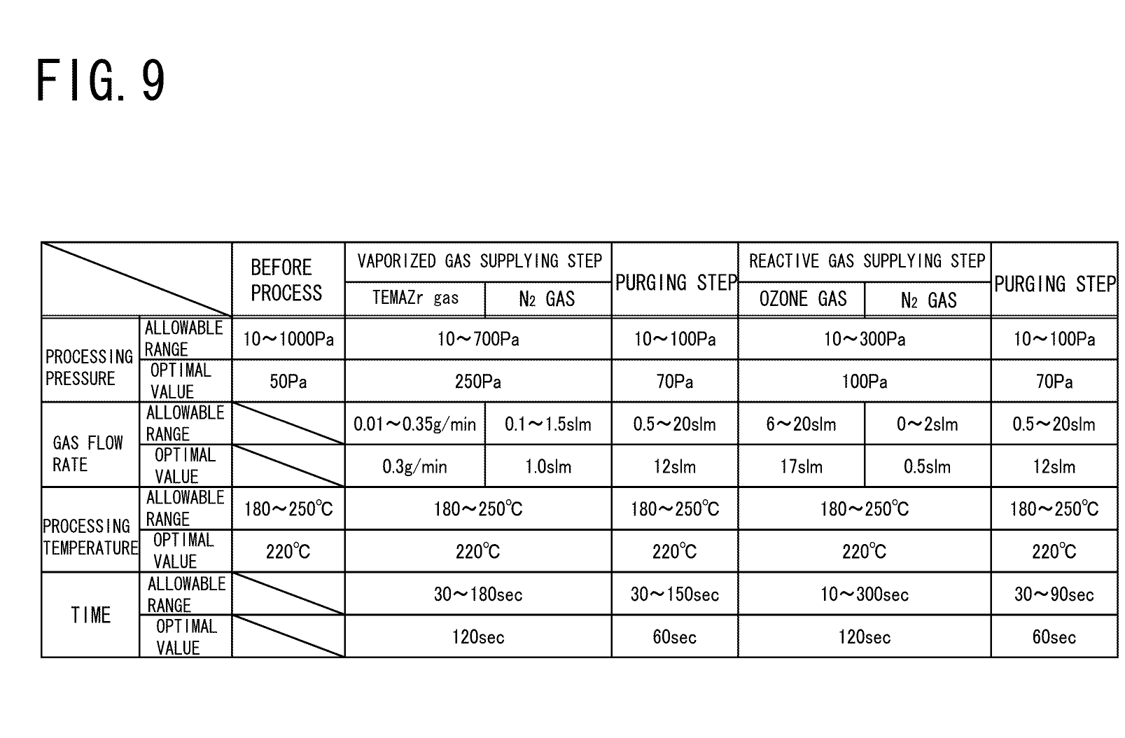

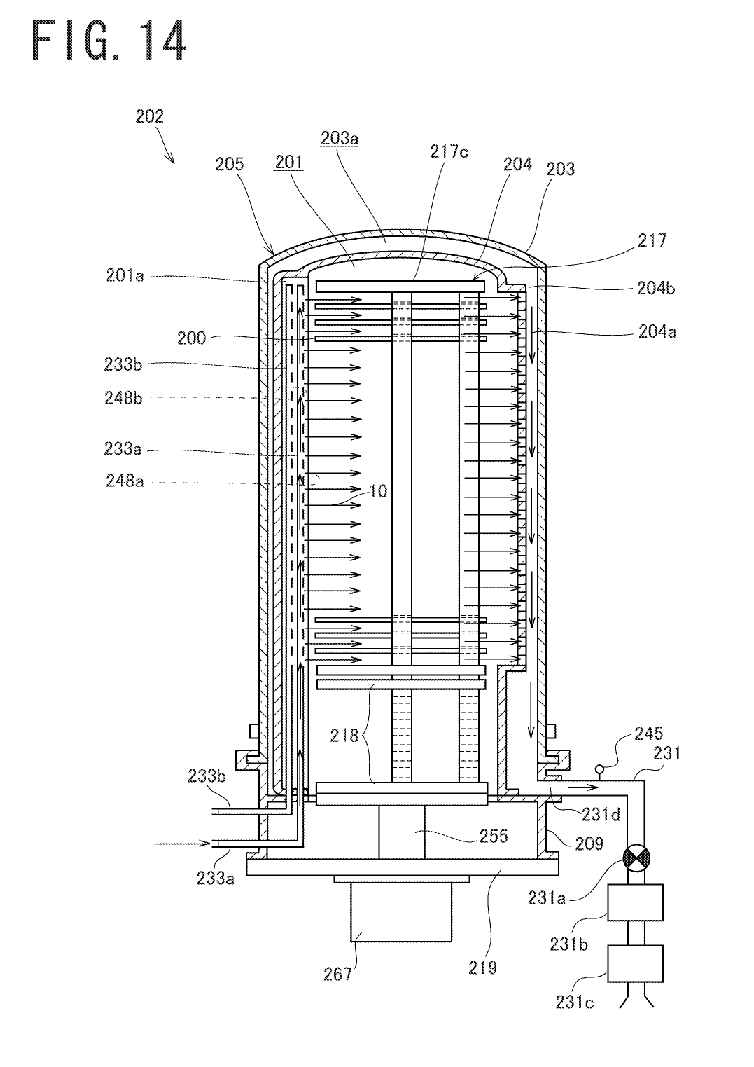

FIG. 1 is a schematic block diagram of a substrate processing apparatus according to an embodiment of the present invention. FIG. 2 is a vertical sectional view of a processing furnace provided in the substrate processing apparatus according to an embodiment of the present invention. FIG. 3 is a perspective view of the inner tube provided in the substrate processing apparatus according to an embodiment of the present invention, showing a case that the gas exhaust hole has a hole shape. FIG. 5 is a horizontal sectional view of a process tube provided in the substrate processing apparatus according to an embodiment of the present invention, showing a case that a preliminary chamber is provided in the inner tube. FIG. 7 is a flowchart of a substrate processing step according to an embodiment of the present invention. FIG. 8 is a sequence view of gas supply in the substrate processing step according to an embodiment of the present invention. FIG. 9 is a table chart exemplifying processing conditions of the substrate processing step according to an embodiment of the present invention. FIG. 14 is a schematic view exemplifying a gas flow generated in the process tube provided in the substrate processing apparatus according to an embodiment of the present invention.

### (1) Structure of the Substrate Processing Apparatus

First, a structural example of a substrate processing apparatus 101 according to an embodiment of the present invention will be described, by using FIG. 1.

As shown in FIG. 1, the substrate processing apparatus 101 according to this embodiment includes a casing 111. In order to carry the wafer (substrate) 200 made of silicon, etc, a cassette 110 is used, which is a wafer carrier (substrate storage container) for storing a plurality of wafers 200. A cassette stage (substrate storage container transfer table) 114 is provided at a front side in the casing 111 (the right side in the figure). The cassette 110 is placed on the cassette stage 114 by an in-step carrying device not shown, and is unloaded to outside the casing 111 from the cassette stage 114.

The cassette 110 is placed on the cassette stage 114 by the in-step carrying device, so that the wafer 200 in the cassette 110 takes a vertical posture, with a wafer charging/discharging vent of the cassette 110 faced upward. The cassette stage 114 is constituted, so that the cassette 110 can be rotated by 90° in a vertical direction toward a rear side of the casing 111, the wafer 200 in the cassette 110 can take a horizontal posture, and the wafer charging/discharging vent of the cassette 110 can be faced rearward.

A cassette rack (substrate storage container placement rack) 105 is installed in approximately a center part of the casing 111 in a lateral direction. A plurality of cassettes 110 are stored in the cassette rack 105 in multiple stages and in multiple rows. A transfer rack 123 for storing the cassettes 110, being carrying objects of a wafer transfer mechanism 125 as will be described later, is provided in the cassette rack 105. Further, a spare cassette rack 107 is provided in an upper part of the cassette stage 114, to store the cassettes 110 preliminarily.

A cassette carrying device (substrate storage container carrying device) 118 is provided between the cassette stage 114 and the cassette rack 105. The cassette carrying device 118 includes a cassette elevator (substrate storage container elevating mechanism) 118a capable of elevating each cassette 110 while holding them, and a cassette carrying mechanism (substrate storage container carrying mechanism) 118b, being a carrying mechanism capable of being horizontally moved while holding the cassette 110. By a cooperative operation of these cassette elevator 118a and cassette carrying mechanism 118b, the cassette 110 is carried among the cassette stage 114, the cassette rack 105, the spare cassette rack 107, and the transfer rack 123.

A wafer transfer mechanism (substrate transfer mechanism) 125 is provided in the rear side of the cassette rack 105. The wafer transfer mechanism 125 includes a wafer transfer device (substrate transfer device) 125a capable of horizontally rotating or linearly moving the wafer 200, and a wafer transfer device elevator (substrate transfer device elevating mechanism) 125b for elevating the wafer transfer device 125a. In addition, the wafer transfer device 125a includes a tweezer (substrate transfer jig) 125c for holding the wafer 200 in a horizontal posture. By the cooperative operation of these wafer transfer device 125a and wafer transfer device elevator 125b, the wafer 200 is picked up from the cassette 110 on the transfer rack 123 and is charged into a boat (substrate holding tool) 217 as will be described later, or the wafer 200 is discharged from the boat 217 and stored in the cassette 110 on the transfer rack 123.

A processing furnace 202 is provided in a rear upper part of the casing 111. An opening (furnace vent) is provided on a lower end of the processing furnace 202, and the opening is opened/closed by a furnace vent shutter (furnace vent opening/closing mechanism) 147. Note that the structure of the processing furnace 202 will be described later.

A boat elevator (substrate holding tool elevating mechanism) 115 is provided in a lower part of the processing furnace 202, which is an elevating mechanism for carrying the boat 217 to inside/outside of the processing furnace 202 by elevating the boat 217. An arm 128, being a coupling tool, is provided on an elevation table of the boat elevator 115. A disc-shaped seal cap 219 is provided on the arm 128 in a horizontal posture, which is a lid member for vertically supporting the boat 217 and air-tightly closing the lower end of the processing furnace 202 when the boat 217 is elevated by the boat elevator 115.

The boat 217 includes a plurality of holding members, so that a plurality of wafers 200 (for example, about 50 to 150 wafers 200) are held in multiple stages in a horizontal posture, with centers thereof aligned in a vertical direction. Detailed structure of the boat 217 will be described later.

A clean unit 134a including a supply fan and a dust-proof filter is provided in the upper part of the cassette rack 105. The clean unit 134a is constituted so that clean air, being cleaned atmosphere, is flown through the casing 111.

Further, the clean unit (not shown) including the supply fan for supplying clean air and the dust-proof filter is installed in a left side end portion of the casing 111, being the opposite side to the side of the wafer transfer device elevator 125b and the boat elevator 115. The clean air blown out from the clean unit not shown is circulated around the wafer transfer device 125a and the boat 217, and thereafter is sucked into an exhaust device not shown, and is exhausted to outside of the casing 111.

### (2) Operation of the Substrate Processing Apparatus

Next, an operation of the substrate processing apparatus 101 according to this embodiment will be described.

First, the cassette 110 is placed on the cassette stage 114 by the in-step carrying device not shown, so that the wafer 200 takes a vertical posture and the wafer charging/discharging vent of the cassette 110 is faced upward. Thereafter, the cassette 110 is vertically rotated by 90° by the cassette stage 114 toward the rear side of the casing 111. As a result, the wafer 200 in the cassette 110 takes a horizontal posture, and the wafer charging/discharging vent of the cassette 110 is faced rearward in the casing 111.

The cassette 110 is automatically carried and transferred to a designated position of the cassette rack 105 or the spare cassette rack 107, by the cassette carrying device 118 and is stored therein temporarily, and thereafter is transferred to the transfer rack 123 from the cassette rack 105 or the spare cassette rack 107, or is directly carried to the transfer rack 123.

When the cassette 110 is transferred to the transfer rack 123, the wafer 200 is picked up from the cassette 110 through the wafer charging/discharging vent, by the tweezer 125c of the wafer transfer device 125a, and is charged into the boat 217 at the rear side of the transfer chamber 124 by a sequential operation of the wafer transfer device 125a and the wafer transfer device elevator 125b. The wafer transfer mechanism 125 that has transferred the wafer 200 to the boat 217, is returned to the cassette 110, so that the next wafer 200 is charged into the boat 217.

When the previously designated number of wafers 200 are charged into the boat 217, the lower end of the processing furnace 202 closed by the furnace vent shutter 147 is opened by the furnace vent shutter 147. Subsequently, by elevating the seal cap 219 by the boat elevator 115, the boat 217 holding a wafer 200 group is loaded into the processing furnace 202. After loading, arbitrary processing is applied to the wafer 200 in the processing furnace 202. Such processing will be described later. After processing, the wafer 200 and the cassette 110 are discharged to outside of the casing 111 in a reversed procedure to the aforementioned procedure.

### (3) Structure of the Processing Furnace

Subsequently, the structure of the processing furnace 202 according to an embodiment of the present invention will be described, with reference to FIG. 2, FIG. 3, and FIG. 5.

### (Processing Chamber)

The processing furnace 202 according to an embodiment of the present invention includes a process tube 205, being a reaction tube, and a manifold 209. The process tube 205 is composed of an inner tube 204 in which wafers 200, being substrates, are stored, and an outer tube 203 surrounding the inner tube 204. The inner tube 204 and the outer tube 203 are made of a non-metal material having heat-resistant properties such as silica (SiO₂) and silicon carbide (SiC) respectively, and has a cylindrical shape with an upper end closed and a lower end opened. The manifold 209 is made of a metal material such as SUS, and has a cylindrical shape with the upper end and the lower end opened. The inner tube 204 and the outer tube 203 are vertically supported by the manifold 209 from the lower end side. The inner tube 204, the outer tube 203, and the manifold 209 are arranged mutually concentrically. The lower end (furnace vent) of the manifold 209 is air-tightly sealed by the seal cap 219 when the boat elevator 115 is elevated. A sealing member (not shown) such as an O-ring for air-tightly sealing an inside of the inner tube 204 is provided between the lower end of the manifold 209 and the seal cap 219.

A processing chamber 201 for processing the wafer 200 is formed inside of the inner tube 204. In the inner tube 204 (inside of the processing chamber 201), the boat 217, being the substrate holding tool, is inserted from below. Inner diameters of the inner tube 204 and the manifold 209 are set to be larger than a maximum outer shape of the boat 217 into which the wafers 200 are charged.

The boat 217 includes upper and lower pair of end plates 217c, and a plurality of (for example three) holding poles 217a vertically constructed between the pair of end plates 217c. The end plates 217c and the holding poles 217a are made of non-metal materials having heat resistance properties such as silica and silicon carbide. In each holding pole 217a, a plurality of holding grooves 217b are formed so as to be arranged at equal intervals along a longitudinal direction of the holding poles 217a. Each holding pole 217a is arranged respectively, so that the holding grooves 217b formed in each holding pole 217a are mutually faced with each other. By inserting an outer peripheral part of the wafer 200 into each holding groove 217b, a plurality of (for example 75 to 100) wafers 200 are held in multiple stages at prescribed intervals (substrate pitch intervals) in approximately a horizontal posture. The boat 217 is mounted on a heat-insulating cap 218 for shielding heat conduction. The heat insulating cap 218 is supported from below by a rotary shaft 255. The rotary shaft 255 is provided so as to pass through a center part of the seal cap 219, while maintaining air-tightly inside of the inner tube 204. A rotation mechanism 267 for rotating the rotary shaft 255 is provided below the seal cap 219. By rotating the rotary shaft 255 by the rotation mechanism 267, the boat 217, with a plurality of wafers 200 mounted thereon, can be rotated while maintaining air-tightly the inside of the inner tube 204.

A heater 207, being a heating mechanism, is provided on the outer periphery of the process tube 205 (outer tube 203) concentrically with the process tube 205. The heater 207 has a cylindrical shape, and is vertically constructed by being supported by a heater base (not shown) as a holding plate. A heat-insulating material 207a is provided on an outer peripheral part and an upper end of the heater 207.

### (Preliminary Chamber and a Gas Nozzle)

A preliminary chamber 201a protruding outward of the inner tube 204 in a radial direction (to the side of the side wall of the outer tube 203) from the side wall of the inner tube 204, is provided along a direction (vertical direction) of stacking the wafers 200. A partition wall is not provided between the preliminary chamber 201a and the processing chamber 201, and the inside of the preliminary chamber and the inside of the processing chamber 201 are communicated with each other, so that the gas can be flown through each other.

In the preliminary chamber 201a, a vaporized gas nozzle 233a, being a first gas nozzle, and a reactive gas nozzle 233b, being a second gas nozzle, are respectively arranged along a peripheral direction of the inner tube 204. The vaporized gas nozzle 233a and the reactive gas nozzle 233b are respectively constituted in an L-shape having a vertical portion and a horizontal portion. Vertical portions of the vaporized gas nozzle 233a and the reactive gas nozzle 233b are respectively arranged (extended) in the preliminary chamber 201a, along the direction of stacking the wafers 200. Horizontal portions of the vaporized gas nozzle 233a and the reactive gas nozzle 233b are respectively provided so as to pass through the side wall of the manifold 209.

A plurality of vaporized gas ejection holes 248a and reactive gas ejection holes 248b are respectively opened on a vertical side face of the vaporized gas nozzle 233a and the reactive gas nozzle 233b in the direction (vertical direction) of stacking the wafers 200. Accordingly, the vaporized gas ejection holes 248a and the reactive gas ejection holes 248b are opened at positions protruded outward of the inner tube 204 in a radial direction from the side wall of the inner tube 204. In addition, the vaporized gas ejection holes 248a and the reactive gas ejection holes 248b are opened at positions (height positions) corresponding to the plurality of wafers 200 respectively. Further, opening diameters of the vaporized gas ejection holes 248a and the reactive gas ejection holes 248b can be suitably adjusted so as to optimize a flow rate distribution and a velocity distribution of the gas in the inner tube 204, and may be equalized from a lower part to an upper part, or may be gradually larger from the lower part to the upper part.

### (Vaporized Gas Supply Unit)

A vaporized gas supply tube 240a is connected to a horizontal end (upper stream side) of the vaporized gas nozzle 233a protruded from the side wall of the manifold 209. A vaporizer 260 for generating vaporized gas, being a first source gas, by vaporizing a liquid source, is connected to the upstream side of the vaporized gas supply tube 240a. An open/close valve 241a is provided in the vaporized gas supply tube 240a. By opening the open/close valve 241a, the vaporized gas generated in the vaporizer 260 is supplied into the inner tube 204 through the vaporized gas nozzle 233a.

The downstream side of a liquid source supply tube 240c for supplying liquid source into the vaporizer 260 and the downstream side of a carrier gas supply tube 240f for supplying carrier gas into the vaporizer 260 are respectively connected to the upstream side of the vaporizer 260.

The upstream of the liquid source supply tube 240c is connected to a liquid source supply tank 266 for storing the liquid source such as TEMAZr. The upstream side of the liquid source supply tube 240c is dipped into the liquid source stored in the liquid source supply tank 266. An open/close valve 243c, a liquid flow rate controller (LMFC) 242c, and an open/close valve 241c are provided sequentially from the upstream side. The downstream side of a compressed gas supply tube 240d for supplying inert gas such as N₂ gas is connected to an upper surface part of the liquid source supply tank 266. The upstream side of the compressed gas supply tube 240d is connected to a compressed gas supply source not shown for supplying inert gas such as He gas, being a compressed gas. An open/close valve 241d is provided in the compressed gas supply tube 240d. By opening the open/close valve 241d, the compressed gas is supplied into the liquid source supply tank 266, and further by opening the open/close valve 243c and the open/close valve 241c, the liquid source in the liquid source supply tank 266 is sent under pressure (supplied) into the vaporizer 260, and the vaporized gas such as TEMAZr gas is generated in the vaporizer 260. In addition, a supply flow rate of the liquid source supplied into the vaporizer 260 (namely, the flow rate of the vaporized gas generated in the vaporizer 260 and supplied into the inner tube 204) can be controlled by the liquid flow rate controller 242c.

The upstream side of the carrier gas supply tube 240f is connected to the carrier gas supply source not shown for supplying inert gas (carrier gas) such as N₂ gas. A flow rate controller (MFC) 242f and an open/close valve 241f are provided in the carrier gas supply tube 240f sequentially from the upstream side. By opening the open/close valve 241f and the open/close valve 241a, the carrier gas is supplied into the vaporizer 260, and the mixed gas of the vaporized gas and the carrier gas generated in the vaporizer 260 is supplied into the inner tube 204 through the vaporized gas supply tube 240a and the vaporized gas nozzle 233a. By supplying the carrier gas into the vaporizer 260, discharge of the vaporized gas from the vaporizer 260 and supply of the vaporized gas into the inner tube 204 can be urged. A supply flow rate of the carrier gas into the vaporizer 260 (namely, the supply flow rate of the carrier gas into the inner tube 204) can be controlled by the flow rate controller 242f.

A vaporized gas supply unit for supplying vaporized gas into the inner tube 204 through the vaporized gas nozzle 233a is constituted mainly by the vaporized gas supply tube 240a, vaporizer 260, open/close valve 241a, liquid source supply tube 240c, open/close valve 243c, liquid flow rate controller 242c, open/close valve 241c, liquid source supply tank 266, compressed gas supply tube 240d, compressed gas supply source not shown, open/close valve 241d, carrier gas supply tube 240f, carrier gas supply source not shown, flow rate controller 242f, and open/close valve 241f.

### (Reactive Gas Supply Unit)

The reactive gas supply tube 240b is connected to a horizontal end (upstream side) of the reactive gas nozzle 233b protruded from the side wall of the manifold 209. An ozonizer 270 for generating (O₃) gas (oxidant agent), being a reactive gas, is connected to the upstream side of the reactive gas supply tube 240b. A flow rate controller (MFC) 242b and an open/close valve 241b are provided in the reactive gas supply tube 240b sequentially from the upstream side. The downstream side of the oxygen gas supply tube 240e is connected to the ozonizer 270. The upstream side of the oxygen gas supply tube 240e is connected to an oxygen gas supply source not shown for supplying oxygen (O₂) gas. An open/close valve 241e is provided in the oxygen gas supply tube 240e. By opening the open/close valve 241e, the oxygen gas is supplied to the ozonizer 270, and by opening the open/close valve 241b, the ozone gas generated in the ozonizer 270 is supplied into the inner tube 204 through the reactive gas supply tube 240b. In addition, the supply flow rate of the ozone gas into the inner tube 204 can be controlled by the flow rate controller 242b.

A reactive gas supply unit for supplying ozone gas into the inner tube 204 through the reactive gas nozzle 233b is constituted mainly by the reactive gas supply tube 240b, ozonizer 270, flow rate controller (MFC) 242b, open/close valve 241b, oxygen gas supply tube 240e, oxygen gas supply source not shown, and open/close valve 241e.

### (Vent Tube)

The upstream side of a vaporized gas vent tube 240i is connected between the vaporizer 260 and the open/close valve 241a in the vaporized gas supply tube 240a. The downstream side of the vaporized gas vent tube 240i is connected to the downstream side of an exhaust tube 231 as will be described later (between an APC valve 231a and a vacuum pump 231b as will be described later). An open/close valve 241i is provided in the vaporized gas vent tube 240i. By closing the open/close valve 241a and opening the open/close valve 241i, supply of the vaporized gas into the inner tube 204 can be suspended, while generation of the vaporized gas in the vaporizer 260 is continued. Although prescribed time is required for stably generating the vaporized gas, supply/suspension of the vaporized gas into the inner tube 204 can be switched in an extremely short time, by a switching operation of the open/close valve 241a and the open/close valve 241i.

Similarly, the upstream side of a reactive gas vent tube 240j is connected between the ozonizer 270 and the flow rate controller 242b in the reactive gas supply tube 240b. The downstream side of the reactive gas vent tube 240j is connected to the downstream side of the exhaust tube 231 (between the APC valve 231a and the vacuum pump 231b). An open/close valve 241j and ozone removal equipment 242j are provided in the reactive gas vent tube 240j sequentially from the upstream side. By closing the open/close valve 241b and opening the open/close valve 241j, supply of the ozone gas into the inner tube 204 can be suspended, while generation of the ozone gas by the ozonizer 270 is continued. Although prescribed time is required for stably generating the ozone gas, supply/suspension of the ozone gas into the inner tube 204 can be switched in an extremely short time, by the switching operation of the open/close valve 241b and the open/close valve 241j.

### (Inert Gas Supply Tube)

The downstream side of the first inert gas supply tube 240g is connected to the downstream side of the open/close valve 241a in the vaporized gas supply tube 240a. An inert gas supply source not shown for supplying inert gas such as N₂ gas, a flow rate controller (MFC) 242g, and an open/close valve 241g are provided in the first inert gas supply tube 240g sequentially from the upstream side. Similarly, the downstream side of the second inert gas supply tube 240h is connected to the downstream side of the open/close valve 241b in the reactive gas supply tube 240b. An inert gas supply source not shown for supplying inert gas such as N₂ gas, a flow rate controller (MFC) 242h, and an open/close valve 241h are provided to the second inert gas supply tube 240h sequentially from the upstream side.

The inert gas from the first inert gas supply tube 240g and the second inert gas supply tube 240h functions as carrier gas, and functions as purge gas.

For example, by closing the open/close valve 241i and opening the open/close valve 241a and the open/close valve 241g, the gas from the vaporizer 260 (mixed gas of the vaporized gas and the carrier gas) can be supplied into the inner tube 204, while being diluted with the inert gas (carrier gas) from the first inert gas supply tube 240g. Similarly, by closing the open/close valve 241j and opening the open/close valve 241b and the open/close valve 241h, the reactive gas from the ozonizer 270 can be supplied into the inner tube 204, while being diluted with the inert gas (carrier gas) from the second inert gas supply tube 240h.

In addition, dilution of the gas can also be performed within the preliminary chamber 201a. Namely, by closing the open/close valve 241i and opening the open/close valve 241a and the open/close valve 241h, the gas from the vaporizer 260 (mixed gas of the vaporized gas and the carrier gas) can be supplied into the inner tube 204, while being diluted with the inert gas (carrier gas) from the second inert gas supply tube 240h in the preliminary chamber 201a. Similarly, by closing the open/close valve 241j and opening the open/close valve 241b and the open/close valve 241g, the ozone gas from the ozonizer 270 can be supplied into the inner tube 204, while being diluted with the inert gas (carrier gas) from the first inert gas supply tube 240g in the preliminary chamber 201a.

Also, by closing the open/close valve 241a and opening the open/close valve 241i, supply of the vaporized gas into the inner tube 204 is suspended while generation of the vaporized gas by the vaporizer 260 is continued, and by opening the open/close valve 241g and the open/close valve 241h, the inert gas (purge gas) from the first inert gas supply tube 240g and the second inert gas supply tube 240h can be supplied into the inner tube 204. Similarly, by closing the open/close valve 241b and opening the open/close valve 241j, supply of the ozone gas into the inner tube 204 is suspended while generation of the ozone gas by the ozonizer 270 is continued, and by opening the open/close valve 241g and the open/close valve 241h, the inert gas (purge gas) from the first inert gas supply tube 240g and the second inert gas supply tube 240h can be supplied into the inner tube 204. Thus, by supplying the inert gas (purge gas) into the inner tube 204, discharge of the vaporized gas or the ozone gas from the inner tube 204 can be urged.

### (A Gas Exhaust Part and a Gas Exhaust Hole)

A gas exhaust part 204b constituting a part of the side wall of the inert tube 204 is provided on the side wall of the inner tube 204, along the direction of stacking the wafers 200. The gas exhaust parts 204b are provided at positions facing a plurality of gas nozzles arranged in the inner tube, across the wafers 200 stored in the inner tube 204. Further, a width of the gas exhaust part 204b in a peripheral direction of the inner tube 204 is set to be wider than the width between gas nozzles of both ends in the plurality of gas nozzles arranged in the inner tube 204. In this embodiment, the gas exhaust part 204b is provided at a position facing the vaporized gas nozzle 233a and the reactive gas nozzle 233b, across the wafer 200 (position of the side 180 degree opposite to the vaporized gas nozzle 233a and the reactive gas nozzle 233b). Also, the width of the gas exhaust part 204b in the peripheral direction of the inner tube 204 is set to be wider than a distance between the vaporized gas nozzle 233a and the reactive gas nozzle 233b.

The gas exhaust holes 204a are opened on the side wall of the gas exhaust part 204b. The gas exhaust holes 204a are opened at positions facing the vaporized gas ejection holes 248a and the reactive gas ejection holes 248b across the wafer 200 (for example, the position of the side about 180 degree opposite to the vaporize gas ejection holes 248a and the reactive gas ejection holes 248b). Each of the gas exhaust holes 204a of this embodiment has a hole shape and are opened at positions (height positions) corresponding to a plurality of wafers 200 respectively. Accordingly, space 203a between the outer tube 203 and the inner tube 204 is communicated with the space in the inner tube 204 through the gas exhaust holes 204a. Note that a hole diameter of the gas exhaust hole 204a can be suitably adjusted to optimize the flow rate distribution and the velocity distribution of the gas in the inner tube 204, and for example, may be set to be the same from the lower part to the upper part, or may be set to be gradually larger from the lower part to the upper part.

In addition, as shown in a horizontal sectional view of FIG. 5, the side wall of the inner tube 204 is constituted, so that distance L2 between the outer edge of the wafer 200 stored in the inner tube 204 and the gas exhaust holes 204a is set to be longer than distance L1 between the outer edge of the wafer 200 stored in the inner tube 204 and the vaporized gas ejection holes 248a. Also, similarly the side wall of the inner tube 204 is constituted, so that the distance L2 between the outer edge of the wafer 200 stored in the inner tube 204 and the gas exhaust holes 204a is set to be longer than the distance L1 between the outer edge of the wafer 200 stored in the inner tube 204 and the reactive gas ejection hole 248b.

Also, the side wall of the inner tube 204 is constituted, so that the distance L2 between the outer edge of the wafer 200 stored in the inner tube 204 and the gas exhaust holes 204a is set to be longer than distance L3 between the side wall of the inner tube 204, on which the gas exhaust holes 204a are not opened, (the side wall of the inner tube 204 not constituted as the gas exhaust part 204b, which is also called “a second part” hereinafter) and the outer edge of the wafer 200 stored in the inner tube 204. Also, the side wall of the inner tube 204 is constituted, so that a distance between the side wall of the inner tube 204, on which the gas exhaust holes 204a are opened, (the side wall of the inner tube 204 constituted as the gas exhaust part 204b, which is also called “a first part”) and the outer edge of the wafer 200 stored in the inner tube 204, and the outer edge of the wafer 200 stored in the inner tube 204, is set to be longer than the distance L3 between the “second part” and the outer edge of the wafer 200 stored in the inner tube 204. Also, the side wall of the inner tube 204 is constituted, so that a curvature radius of the “first part” is set to be smaller than the curvature radius of the “second part”. Further, the side wall of the inner tube 204 is constituted, so that the “first part” is protruded outward of the inner tube 204 in a radial direction (to the side of the outer tube 203) from the “second part”.

When a corner part exists on the side wall (“first part”) of the inner tube 204 constituting the gas exhaust part 204b, gas flows in whirls in the periphery of the corner part in some cases. Therefore, a shape of an inner wall of the gas exhaust part 204b is preferably set to be smooth. However, when the gas exhaust part 204b is formed by forming a horizontal sectional face of the inner tube 204 into an elliptic shape, the distance L3 between the side wall (“second part”) of the inner tube 204 not constituted as the gas exhaust part 204b and the outer edge of the wafer 200 is set to be larger in some cases. Then, an effect of the side flow/side vent system of supplying the gas to the wafer 200 from the horizontal direction is reduced in some cases. Accordingly, it is preferable to set a width and a shape of the gas exhaust part 204b, so that the gas that should be flown between wafers 200 does not flow between the inner wall (inner wall of the “second part”) of the inner tube 204 and the outer edge of the wafer 200.

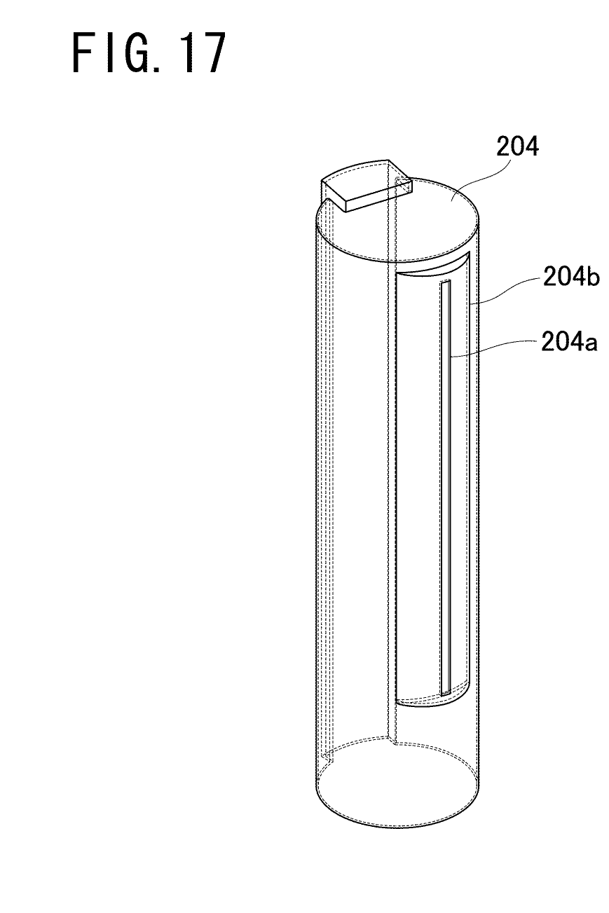

Further, a height position of the lower end of the gas exhaust part 204b is preferably set corresponding to a height position of the wafer 200 of a lowermost end of the wafers 200 loaded into the processing chamber 201. Similarly, a height position of an upper end of the gas exhaust part 204b is preferably set corresponding to the height position of the wafer 200 of an uppermost end of the wafers 200 loaded into the processing chamber 201. When the gas exhaust part 204b is provided in an area where the wafer 200 does not exist, the gas that should be flown between wafers 200 flows to the area where the wafer 200 does not exist, and the effect of the side flow/side vent system is reduced in some cases. FIG. 17 shows a modified example of the inner tube 204 according to this embodiment, which is a schematic view showing a state in which a ceiling part of the gas exhaust part 204b is set lower than a ceiling part of the inner tube 204.

### (Exhaust Unit)

The exhaust tube 231 is connected to the side wall of the manifold 209. In the exhaust tube 231, a pressure sensor 245, being a pressure detector; an APC (Auto Pressure Controller) valve 231a, being a pressure adjuster; a vacuum pump 231b, being a vacuum exhaust device; and a detoxifying facility 231c for removing hazardous components from exhaust gas, are provided sequentially from the upstream side. By adjusting an opening degree of the open/close valve of the APC valve 242 while operating the vacuum pump 231b, the inside of the inner tube 204 can be set to be a desired pressure. The exhaust unit is constituted mainly by the exhaust tube 231, pressure sensor 245, APC valve 231a, vacuum pump 231b, and detoxifying facility 231c.

As described above, the space 203a between the outer tube 203 and the inner tube 204 is communicated with the space in the inner tube 204 through the gas exhaust hole 204a. Therefore, by exhausting the space 203a between the outer tube 203 and the inner tube 204 by the exhaust unit while supplying gas into the inner tube 204 through the vaporized gas nozzle 233a or the reactive gas nozzle 233b, a gas flow 10 in a horizontal direction from the vaporized gas ejection holes 248a and the reactive gas ejection holes 248b to the gas exhaust holes 204a, is generated in the inner tube 204. Such a state is shown in FIG. 14.

### (Controller)

A controller 280, being a control part, is connected to the heater 207, APC valve 231a, vacuum pump 231b, rotation mechanism 267, boat elevator 215, open/close valves 241a, 241b, 241c, 243c, 241d, 241e, 241f, 241g, 241h, 241i, 241j, liquid flow rate controller 242c, and flow rate controllers 242b, 242f, 242g, 242h, etc, respectively. The controller 280 performs control of temperature adjusting operation of the heater 207, opening/closing and pressure adjusting operation of the APC valve 231a, start/suspension of the vacuum pump 231b, rotation speed adjustment of the rotation mechanism 267, elevating operation of the boat elevator 215, opening/closing operation of the open/close valves 241a, 241b, 241c, 243c, 241d, 241e, 241f, 241g, 241h, 241i, 241j, and the flow rate adjustment, etc, by the liquid flow rate controllers 242c and flow rate controllers 242b, 242f, 242g, 242h.

Note that the controller 280 controls the gas supply unit and the exhaust unit, so as to alternately supply at least two kinds of gases into the inner tube 204 without mixing them with each other. Then, the controller 280 controls the gas supply unit and the exhaust unit, so that the pressure in the inner tube 204 is set to be 10 Pa or less and 700 Pa or more, when the gas is supplied into the inner tube 204. Specifically, when the vaporized gas is supplied into the inner tube 204, the controller 280 controls the gas supply unit and the exhaust unit, so that the pressure in the inner tube 204 is set to be 10 Pa or more and 700 Pa or less (preferably 250 Pa). Further, the controller 280 controls the gas supply unit and the exhaust unit, so that the pressure in the inner tube 204 is set to be 10 Pa or more and 300 Pa or less (preferably 100 Pa), when the reactive gas is supplied into the inner tube 204. Such an operation will be described later.

### (4) Substrate Processing Step

Subsequently, the substrate processing step, being an embodiment of the present invention, will be described, with reference to FIG. 7 to FIG. 9. Note that this embodiment shows a method of forming a high dielectric constant film (ZrO₂ film) on the wafer 200, by an ALD (Atomic Layer Deposition) method, being one of CVD (Chemical Vapor Deposition) methods, by using the TEMAZr gas, being the vaporized gas, and the ozone gas, being the reactive gas, and is executed as one step of the manufacturing steps of a semiconductor device. Note that in the description hereinafter, an operation of each part constituting the substrate processing apparatus 101 is controlled by the controller 280.

### (Substrate Loading Step (S10))

First, a plurality of wafers 200 are charged into the boat 217 (wafer charge). Then, the boat 217 holding the plurality of wafers 200 is lifted by the boat elevator 215 and is loaded into the inner tube 204 (boat loading). In this state, the seal cap 219 is set in a state of sealing the lower end of the manifold 209 through O-ring 220b. Note that in the substrate loading step (S10), purge gas is preferably supplied into the inner tube continuously by opening the open/close valve 241g and the open/close valve 241h.

### (Pressure Reducing and Temperature Increasing Step (S20))

Subsequently, the open/close valve 241g and the open/close valve 241h are closed, and the inside of the inner tube 204 is exhausted by the vacuum pump 231b, so that the inside of the inner tube 204 (inside of the processing chamber 201) is set in a desired processing pressure (vacuum degree). At this time, based on a pressure measured by the pressure sensor 245, an opening degree of the APC valve 231a is feedback-controlled. In addition, a power supply amount to the heater 207 is adjusted so that the surface of the wafer 200 is set to be a desired processing temperature. At this time, based on temperature information detected by the temperature sensor, a power-supply condition to the heater 207 is feedback-controlled. Then, the boat 217 and the wafer 200 are rotated by the rotation mechanism 267.

Conditions at the time of ending the pressure reducing and temperature increasing step (S20) are, for example, as follows:

processing pressure: 10 to 1000 Pa, preferably 50 Pa,

processing temperature: 180 to 250° C., preferably 220° C.

### (Film-Forming Step)

Subsequently, the steps from vaporized gas supplying step (S31) to purging step (S34) as will be described later are set as one cycle, and by repeating this cycle prescribed number of times, the high dielectric constant film (ZrO₂ film) of a prescribed thickness is formed on the wafer 200. FIG. 8 exemplifies a supply sequence of the gas in each step from the vaporized gas supplying step (S31) to the purging step (S34).

### (Vaporized Gas Supplying Step (S31))

First, compressed gas is supplied into the liquid source supply tank 266 by opening the open/close valve 241d. Then, the open/close valves 243c, 241c are opened, to thereby send TEMAZr, being the liquid source, under pressure, into the vaporizer 260 from the liquid source supply tank 266, then TEMAZr is vaporized in the vaporizer 260, to thereby generate TEMAZr gas (vaporized gas). Further, the N₂ gas (carrier gas) is supplied into the vaporizer 260 by opening the open/close valve 241f. The open/close valve 241a is closed until the TEMAZr gas is stably generated, and by opening the open/close valve 241i, the mixed gas of the TEMAZr gas and the N₂ gas is discharged from the vaporized gas vent tube 240i.

When the TEMAZr gas is stably generated, the open/close valve 241i is closed and the open/close valve 241a is opened, to thereby supply the mixed gas of the TEMAZr gas and the N₂ gas into the inner tube 204 through the vaporized gas nozzle 233a. At this time, the open/close valve 241g is opened and the mixed gas from the vaporizer 260 is supplied into the inner tube 204 while being diluted with the N₂ gas (carrier gas) from the first inert gas supply tube 240g. At this time, the flow rate of the TEMAZr gas is set to be, for example, 0.35 g/min, the flow rate of the N₂ gas from the carrier gas supply tube 240f is set to be, for example, 1 slm, and the flow rate of the N₂ gas from the first inert gas supply tube 240g is set to be, for example, 8 slm.

The mixed gas supplied into the inner tube 204 from the vaporized gas nozzle 233a becomes the gas flow 10 in the horizontal direction toward the gas exhaust holes 204a from the vaporized gas ejection holes 248a as shown in FIG. 14, and is exhausted from the exhaust tube 231. At that time, the TEMAZr gas is supplied to the surface of each stacked wafer respectively, and a gas molecule of the TEMAZr gas is respectively adsorbed on each wafer 200.

After elapse of a prescribed time (for example 120 seconds), the open/close valve 241a is closed and the open/close valve 241i is opened, and the supply of the TEMAZr gas into the inner tube 204 is suspended, while generation of the TEMAZr gas is continued. Note that the supply of the N₂ gas into the vaporizer 260 is continued, with the open/close valve 241f opened.

### (Purging Step (S32))

Subsequently, the open/close valve 241g and the open/close valve 241h are opened, to thereby supply the N₂ gas (purge gas) into the inner tube 204. At this time, the flow rate of the N₂ gas from the first inert gas supply tube 240g is set to be, for example, 5 slm, and the flow rate of the N₂ gas from the second inert gas supply tube 240h is set to be, for example, 4 slm. Thus, the discharge of the TEMAZr gas from the inner tube 204 is urged. After elapse of a prescribed time (for example 20 seconds), when an atmosphere in the inner tube 204 is replaced with the N₂ gas, the open/close valve 241g and the open/close valve 241h are closed, and the supply of the N₂ gas into the inner tube 204 is suspended. Then, the inside of the inner tube 204 is further exhausted for a prescribed time (for example, 20 seconds).

### (Reactive Gas Supplying Step (S33))

Subsequently, the open/close valve 241e is opened, and the oxygen gas is supplied to the ozonizer 270, to thereby generate the ozone gas (oxidant agent), being the reactive gas. The open/close valve 241b is closed until the ozone gas is stably generated, and by opening the open/close valve 241j, the ozone gas is discharged from the reactive gas vent tube 240j.

When the ozone gas is stably generated, the open/close valve 241j is closed, and the open/close valve 241b is opened, to thereby supply the ozone gas into the inner tube 204 through the reactive gas nozzle 233b. At this time, the open/close valve 241g is opened, and the ozone gas from the reactive gas nozzle 233b is supplied into the inner tube 204 while being diluted with the N₂ gas (carrier gas) from the first inert gas supply tube 240g in the preliminary chamber 201a. At this time, the flow rate of the ozone gas is set to be, for example, 6 slm, and the flow rate of the N₂ gas from the first inert gas supply tube 240g is set to be, for example, 2 slm.

The ozone gas supplied into the inner tube 204 from the reactive gas nozzle 233b becomes the gas flow 10 in the horizontal direction toward the gas exhaust holes 204a from the reactive gas ejection holes 248b as shown in FIG. 14, and is discharged from the exhaust tube 231. At that time, the ozone gas is supplied to the surface of each wafer 200 respectively, and chemical reaction occurs between the gas molecule of the TEMAZr gas adsorbed on the wafer 200 and the ozone gas, to thereby generate the high dielectric constant film (ZrO₂ film) of one atomic layer to several atomic layers on the wafer 200.

When the supply of the reactive gas is continued for a prescribed time, the open/close valve 241b is closed, and the open/close valve 241j is opened, to thereby suspend the supply of the reactive gas into the inner tube 204 while the generation of the ozone gas is continued.

### (Purging Step (S34)

Subsequently, the open/close valve 241g and the open/close valve 241h are opened, to thereby supply the N₂ gas (purge gas into the inner tube 204. At this time, the flow rate of the N₂ gas from the first inert gas supply tube 240g and the second inert gas supply tube 240h is set to be, for example, 4 slm respectively. Thus, the discharge of the ozone gas and a reaction by-product from the inner tube 204 is urged. After elapse of a prescribed time (for example 10 seconds), when the atmosphere in the inner tube 204 is replaced with the N₂ gas, the open/close valve 241g and the open/close valve 241h are closed, to thereby suspend the supply of the N₂ gas into the inner tube 204. Then, the inside of the inner tube 204 is exhausted for a prescribed time (for example, 15 seconds).

Thereafter, the steps from the vaporized gas supplying step (S31) to purging step (S34) are set as one cycle, and by repeating this cycle prescribed number of times, the TEMAZr gas and the ozone gas are alternately supplied into the inner tube 204 without mixing them with each other, to thereby form the high dielectric constant film (ZrO₂ film) of a prescribed thickness on the wafer 200. Note that the processing conditions in each step are not necessarily limited to the aforementioned conditions, and for example, can be conditions as shown in FIG. 9, for example.

### <Processing Conditions of the Vaporized Gas Supplying Step (S31)>

Processing pressure: 10 to 700 Pa, preferably 250 Pa,

Flow rate of the TEMAZr gas: 0.01 to 0.35 g/min, preferably 0.3 g/min,

Flow rate of the N₂ gas: 0.1 to 1.5 slm, preferably 1.0 slm,

Processing temperature: 180 to 250° c., preferably 220° C.

Execution time: 30 to 180 seconds, preferably 120 seconds.

### <Processing Condition of the Purging Step (S32)>

Processing pressure: 10 to 100 Pa, preferably 70 Pa,

Flow rate of the N₂ gas: 0.5 to 20 slm, preferably 12 slm,

Processing temperature: 180 to 250° C., preferably 220° C.

Execution time: 30 to 150 seconds, preferably 60 seconds.

### <Processing Conditions of the Reactive Gas Supplying Step (S33)>

Processing pressure: 10 to 300 Pa, preferably 100 Pa,

Flow rate of the ozone gas: 6 to 20 slm, preferably 17 slm,

Flow rate of the N₂ gas: 0 to 2 slm, preferably 0.5 slm,

Processing temperature: 180 to 250° C., preferably 220° C.

Execution time: 10 to 300 seconds, preferably 120 seconds.

### <Processing Conditions of the Purging Step (S34)>

Processing pressure: 10 to 100 Pa, preferably 70 Pa,

Flow rate of the N₂ gas: 0.5 to 20 slm, preferably 12 slm,

Processing temperature: 180 to 250° C., preferably 220° C.

Execution time: 10 to 90 seconds, preferably 60 seconds.

### (Pressure Boosting Step (S40), Substrate Unloading Step (S50))

After the high dielectric constant film (ZrO₂ film) of a prescribed thickness is formed on the wafer 200, the opening degree of the APC valve 231a is set to be small, then the open/close valve 241g and the open/close valve 241h are opened, to thereby supply the purge gas into the inner tube 204 until the pressure inside of the process tube 205 (inside of the inner tube 204 and the outer tube 203) reaches the atmospheric pressure (S40). Then, the wafer 200, with a film already formed thereon, is unloaded from the inner tube 204, by a procedure reverse to the substrate loading step (S10). In addition, in the substrate unloading step (S50), preferably the open/close valve 241g and the open/close valve 241h are opened, to thereby continue the supply of the purge gas into the inner tube 204.

### (5) Advantage of this Embodiment

According to this embodiment, one or a plurality of advantages are exhibited as shown below.

(a) The side wall of the inner tube 204 of this embodiment is constituted, so that the distance L2 between the outer edge of the wafer 200 stored in the inner tube 204 and the gas exhaust holes 204a is set to be longer than the distance L1 between the outer edge of the wafer 200 stored in the inner tube 204 and the vaporized gas ejection holes 248a. Also, similarly the side wall of the inner tube 204 is constituted, so that the distance L2 between the outer edge of the wafer 200 store in the inner tube 204 and the gas exhaust holes 204a is set to be longer than the distance L1 between the outer edge of the wafer 200 stored in the inner tube 204 and the reactive gas ejection holes 248b. Thus, by securing the distance between the outer edge of the wafer 200 and the gas exhaust holes 204a to be longer, the area, where the velocity of the gas flow 10 is increased, can be distanced from the wafer 200 and the velocity of the gas flow 10 on the wafer 200 can be uniformized. Then, the flow rate of the gas supplied to the wafer 200 can be uniformized and the uniformity of the film thickness can be improved.

(b) Further, the side wall of the inner tube 204 of this embodiment is constituted, so that the distance L2 between the outer edge of the wafer 200 stored in the inner tube 204 and the gas exhaust holes 204a is set to be longer than the distance L3 between the side wall (“second part”) of the inner tube 204, with no gas exhaust holes 204a opened, and the outer edge of the wafer 200 stored in the inner tube 204. Thus, by securing the distance between the outer edge of the wafer 200 and the gas exhaust holes 204a to be longer, the area, where the velocity of the gas flow 10 is increased, can be distanced from the wafer 200, and the velocity of the gas flow 10 on the wafer 200 can be uniformized. Then, the flow rate of the gas supplied to the wafer 200 can be uniformized and the uniformity of the film thickness can be improved.

(c) Moreover, the side wall of the inner tube 204 of this embodiment is constituted, so that the distance between the side wall (“first part”) of the inner tube 204, with the gas exhaust holes 204a opened, and the outer edge of the wafer 200 stored in the inner tube 204 is set to be longer than the distance L3 between the “second part” and the outer edge of the wafer 200 stored in the inner tube 204. As a result, the distance between the outer edge of the wafer 200 and the gas exhaust holes 204a can be secured longer, the area, where the velocity of the gas flow 10 is increased, can be distanced from the wafer 200, and the velocity of the gas flow 10 on the wafer 200 can be uniformized. Then, the flow rate of the gas supplied to the wafer 200 can be uniformized, and the uniformity of the film thickness can be improved.

(d) Further, the side wall of the inner tube 204 of this embodiment is constituted, so that the curvature radius of the “first part” is set to be smaller than the curvature radius of the “second part”. As a result, the distance between the outer edge of the wafer 200 and the gas exhaust holes 204a can be secured longer, and the area, where the velocity of the gas flow 10 is increased, can be distance from the wafer 200, and the velocity of the gas flow 10 on the wafer 200 can be uniformized. Then, the flow rate of the gas supplied to the wafer 200 can be uniformized, and the uniformity of the film thickness can be improved.

(e) In addition, the side wall of the inner tube 204 of this embodiment is constituted so as to protrude outward of the inner tube 204 in the radial direction (to the side of the outer tube 203) from the “second part”. As a result, the distance between the outer edge of the wafer 200 and the gas exhaust holes 204a can be secured longer, and the area, where the velocity of the gas flow 10 is increased, can be distanced from the wafer 200, and the velocity of the gas flow 10 on the wafer 200 can be uniformized. Then, the flow rate of the gas supplied to the wafer 200 can be uniformized, and the uniformity of the film thickness can be improved.

### Examples

Examples of the present invention will be described hereinafter, compared with comparative examples.

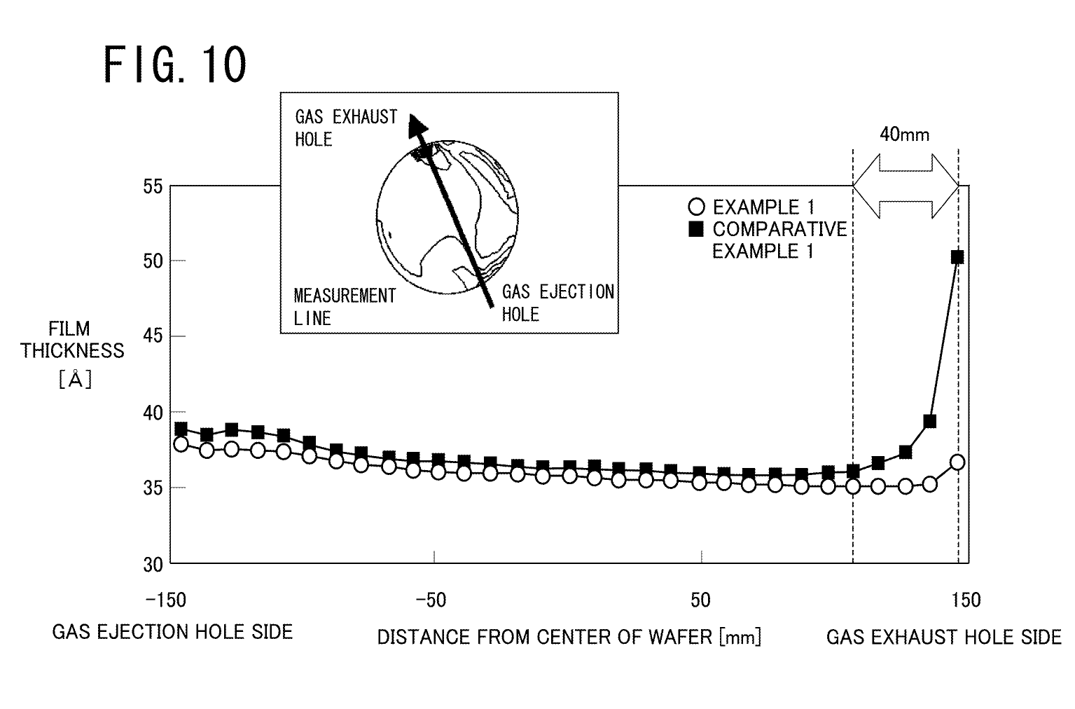

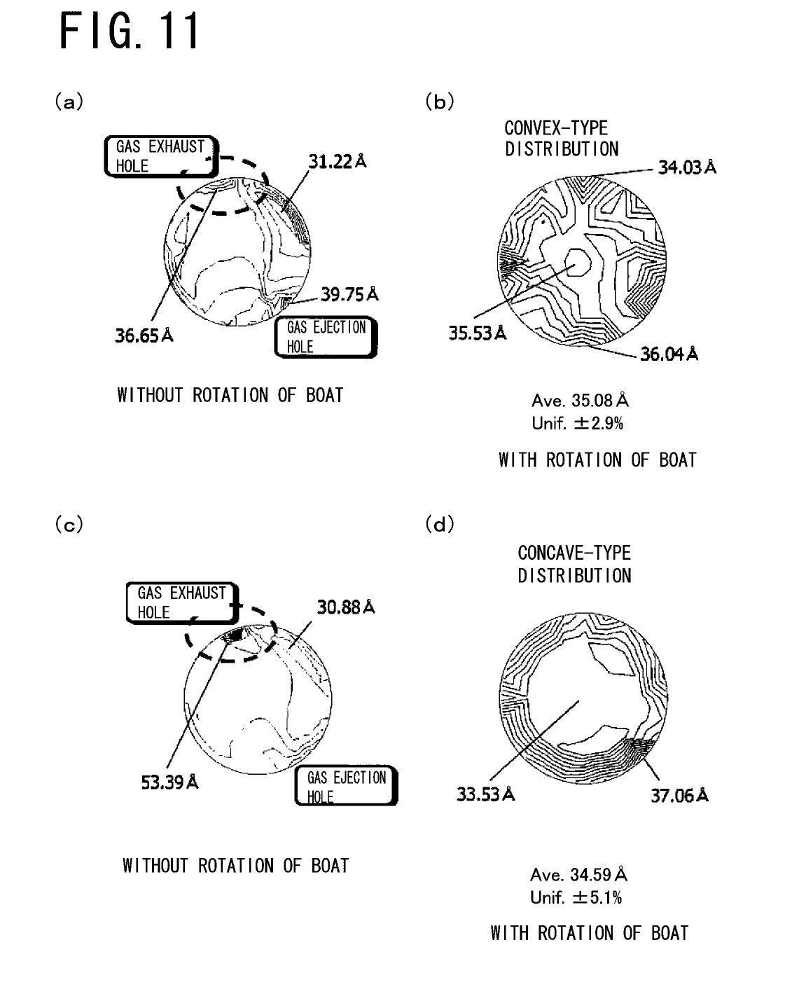

FIG. 10 is a graph chart showing a measurement result of a film thickness distribution of a thin film formed on the wafer 200, wherein symbol ◯ indicates an example 1, symbol ▪ indicates a comparative example 1, respectively. In FIG. 10, the distance from the center of the wafer 200 is taken on the horizontal axis, and the film thickness of the ZrO₂ film formed on the wafer 200 is taken on the vertical axis. FIG. 11 is a schematic view showing the film thickness distribution of the thin film formed on the wafer by a contour line, wherein FIG. 11A shows example 1 of the present invention, FIG. 11B shows example 2 of the present invention, FIG. 11C shows comparative example 1, and FIG. 11D shows comparative example 2, respectively.

In the example 1 shown by symbol ◯ and FIG. 11A, the distance L2 between the outer edge of the wafer 200 stored in the inner tube 204 and the gas exhaust holes 204a was set to be 48 mm, and the ZrO₂ film was formed on the wafer 200 without rotating the wafer 200. The other conditions are the same as those of the aforementioned embodiments. As a result, the film thickness of the ZrO₂ film in the example 1 was approximately uniformized in the surface of the wafer 200. Specifically, the film thickness at the side of the vaporized gas ejection holes 248a and the reactive gas ejection holes 248b was 39.75 Å and was thickest at this place, and was 31.22 Å at a place of thinnest film thickness. In addition, the film thickness at the side of the gas exhaust holes 204a was 36.65 Å.

In the example 2 shown in FIG. 11B, the distance L2 between the outer edge of the wafer 200 stored in the inner tube 204 and the gas exhaust holes 204a was set to be 48 mm, and the ZrO₂ film was formed on the wafer 200 while rotating the wafer 200. The other conditions are the same as those of the example 1. As a result, the film thickness of the ZrO₂ film in the example 2 was further uniformized over the surface of the wafer 200. Specifically, the ZrO₂ film has a loose convex shape as a whole, and the outer edge portion of the wafer 200 was 34.03 to 36.65 Å, and the center part of the wafer 200 was 35.53 Å, and the uniformity was ±2.9. Note that, an average thickness was 35.08 Å.

In the comparative example 1 shown in symbol ▪, and FIG. 11C, the distance L2 between the outer edge of the wafer 200 stored in the inner tube 204 and the gas exhaust holes 204a was set to be 18.5 mm, and the ZrO₂ film was formed on the wafer 200 without rotating the wafer 200. The other conditions are the same as those of the example 1. As a result, the film thickness of the ZrO₂ film in the comparative example 1 was extremely large on the side of the gas exhaust holes 204 and was non-uniform, if compared with the film thickness of the example 1. Specifically, there was no great difference in the film thickness distribution of the ZrO₂ film, if compared with that of the example 1, in the vicinity of the vaporized gas ejection holes 248a and the reactive gas ejection holes 248b and in the vicinity of the center of the wafer 200. However, the film thickness of the ZrO₂ film was rapidly increased in a range from an area in the vicinity of 40 mm from the gas exhaust holes 204a to side of the gas exhaust holes 204a, with a maximum film thickness of the ZrO₂ film being 53.39 Å. Note that the thinnest film thickness was 30.88 Å. From such a measurement result, it is found that by setting the distance L2 between the outer edge of the wafer 200 stored in the inner tube 204 and the gas exhaust holes 204a to be 40 mm or more, the area, where the velocity of the gas flow 10 is increased, can be distanced from the wafer 200, and the uniformity of the film thickness can be improved.

In the comparative example 2 shown in FIG. 11D, the distance L2 between the outer edge of the wafer 200 stored in the inner tube 204 and the gas exhaust holes 204a was set to be 18.5 mm, and the ZrO₂ film was formed on the wafer 200 while rotating the wafer 200. The other conditions are the same as those of the comparative example 1. As a result, the film thickness of the ZrO₂ film in the example 2 was non-uniform, compared with that of the example 2. Specifically, the ZrO₂ film had a clear concave shape as a whole, with the outer edge portion of the wafer 200 being 37.06 Å, and the center part of the wafer 200 being 33.53 Å, and the uniformity being ±5.1%. Note that, the average thickness was 34.59 Å.

Also, in the example 3 of the present invention, the distance L2 between the outer edge of the wafer 200 stored in the inner tube 204 and the gas exhaust holes 204a was set to be 40 mm. Further, the distance L3 between the side wall (“second part”) of the inner tube 204, with no gas exhaust holes 204a opened therein, and the outer edge of the wafer 200 stored in the inner tube 204, was set to be a distance not allowing the inner tube 204 and the boat 217 to be brought into contact with each other, and was set to be 13 mm. Moreover, the distance between an outer wall of the inner tube 204 and an inner wall of the outer tube 203 was set to be a distance capable of securing a necessary sufficient conductance between the inner tube 204 and the outer tube 203. Moreover, the radius of the wafer 200 was set to be 150 mm. In such a case also, similar advantages of the example 1 and the example 2 could be obtained.

### Other Embodiments of the Present Invention

Each of the gas exhaust holes 204a of the present invention is not necessarily limited to a hole shape as shown in FIG. 3, and is not limited to a case of being opened at positions (height positions) corresponding to a plurality of wafers 200 respectively. For example, one gas exhaust hole 204a may be provided with respect to three to five wafers 200. Note that in such a case also, preferably the vaporized gas ejection holes 248a and the reactive gas ejection holes 248b are opened respectively at positions (height positions) corresponding to the plurality of wafers 200, respectively.

The shape of the gas exhaust hole 204a of the present invention is not necessarily limited to the hole shape as shown in FIG. 3, and for example, may be a slit shape opened along the direction of stacking the wafers 200 as shown in FIG. 4.

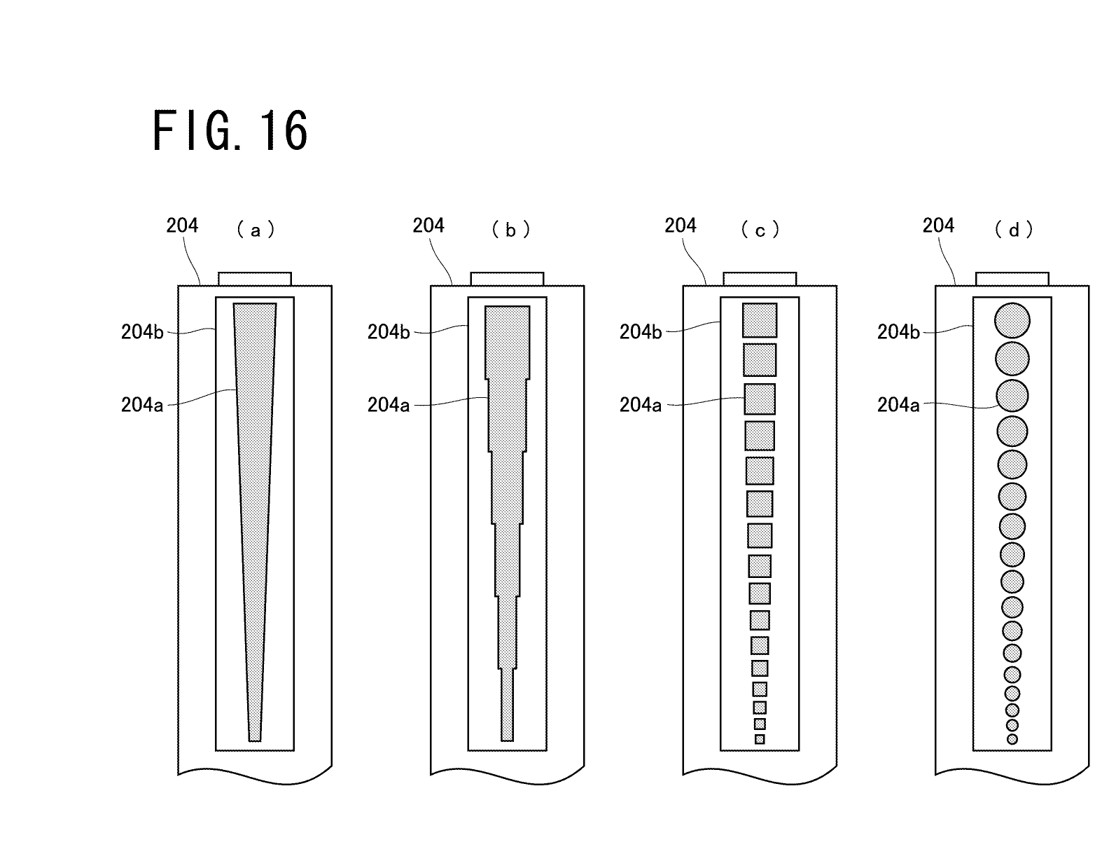

An opening width of each gas exhaust hole 204a can be suitably adjusted so as to optimize the flow rate distribution and a velocity distribution of the gas in the inner tube 204, and for example, is not limited to a case of equalizing them from the lower part to the upper part, and may be set to be gradually smaller toward the lower part from the upper part. This is because as exemplified in FIG. 2, when the exhaust tube 231 is provided in the lower part of the processing chamber 201, by setting the opening width of the gas exhaust hole 204a to be gradually smaller toward the lower part from the upper part, the flow velocity of the gas supplied to the surface of the wafer 200 can be uniformized between wafers 200. FIG. 16 exemplifies a case that the opening width of the gas exhaust holes 204a is set to be gradually smaller toward the lower part from the upper part (namely toward the vicinity of the exhaust tube). A gas exhaust hole 204a shown in FIG. 16A is formed into a slit shape in which the opening width is continuously narrowed toward the lower part from the upper part, the gas exhaust hole 204a shown in FIG. 16B is formed into a slit shape in which the opening width is narrowed step by step toward the lower part from the upper part, the gas exhaust holes 204a shown in FIG. 16C are formed into square holes in which the opening width is narrowed step by step toward the lower part from the upper part, and the gas exhaust holes 204a shown in FIG. 16D are formed into round holes in which the opening width is narrowed step by step toward the lower part from the upper part. Note that when the exhaust tube 231 is provided in the upper part of the processing chamber 201, the opening width of the gas exhaust hole 204a may be set to be gradually smaller toward the upper part from the lower part.

The distance L2 between the outer edge of the wafer 200 stored in the inner tube 204 and the gas exhaust holes 204a is not limited to a case that it is uniform in a vertical direction of the processing furnace 201, and may be varied in the vertical direction. For example, when the exhaust tube 231 is provided in the lower part of the processing chamber 201, an exhaust power is strong in the wafer 200 of the lower part of the boat 217, and the film is likely to be formed thick. Therefore, the distance L2 may be set to be long in the lower part of the processing furnace 201.

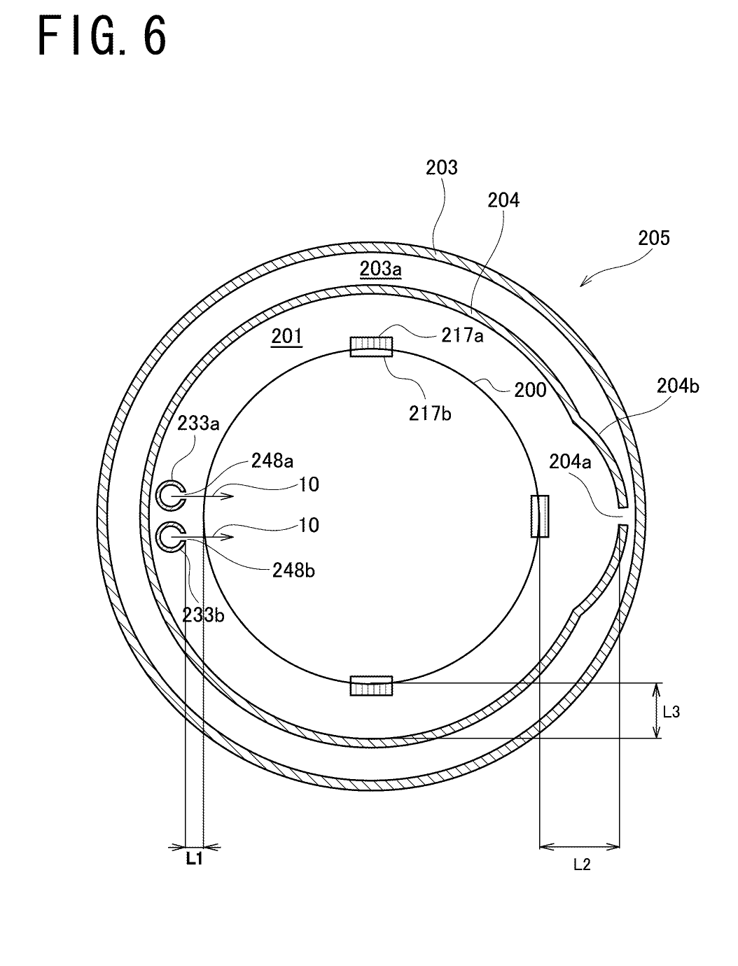

The present invention is not limited to a case that the preliminary chamber 201a is provided in the inner tube 204. For example, as shown in FIG. 6, it is also acceptable that the preliminary chamber 201a is not provided in the inner tube 204, and the vaporized gas nozzle 233a and the reactive gas nozzle 233b are directly provided in the inner tube 204. In such a case also, the side wall of the inner tube 204 is constituted so that the distance L2 between the outer edge of the wafer 200 stored in the inner tube 204 and the gas exhaust holes 204a is set to be longer than the distance L1 between the outer edge of the wafer 200 stored in the inner tube 204 and the vaporized gas ejection holes 248a. Also, similarly, the side wall of the inner tube 204 is constituted so that the distance L2 between the outer edge of the wafer 200 stored in the inner tube 204 and the gas exhaust holes 204a is set to be longer than the distance L1 between the outer edge of the wafer 200 stored in the inner tube 204 and the reactive gas ejection holes 248b.

In the aforementioned embodiment, TEMAZr was used as the liquid source. However, the present invention is not limited to such a mode. Namely, TEMAH (Tetrakis Ethyl Methyl Amino Hafnium) may be used as the liquid source, and other organic compound or chloride containing any one of Si atom, Hf atom, Zr atom, Al atom, Ta atom, Ti atom, Ru atom, Ir atom, Ge atom, Sb atom, Te atom, may also be used. Also, the used gas is not limited to the TEMAZr gas obtained by vaporizing TEMAZr as a first source gas, and the TEMAH gas obtained by vaporizing TEMAH and other gases obtained by vaporizing or decomposing the organic compound or chloride, containing any one of the Si atom, Hf atom, Zr atom, Al atom, Ta atom, Ti atom, Ru atom, Ir atom, Ge atom, Sb atom, Te atom, may also be used.

In the aforementioned embodiment, the ozone gas (oxidant agent) is used as the reactive gas. However, the oxidant agent other than the ozone gas may also be used. Further, a nitriding agent such as ammonia may also be used as the reactive gas.

In the aforementioned embodiment, explanation has been given for a case that the ZrO₂ film is formed on the wafer 200. However, in addition, the present invention can be suitably applied to a case that any one of an Hf oxide film, an Si oxide film, an Al oxide film, a Ta oxide film, a Ti oxide film, an Ru oxide film, an Ir oxide film, an Si nitride film, an Al nitride film, a Ti nitride film, and a GeSbTe film is formed on the wafer 200.

In the aforementioned embodiment, explanation has been given for a case that the ALD method is used, for alternately supplying the vaporize gas, being the first source gas, and the reactive gas, being the second source gas, onto the wafer 200. However, the present invention is not limited to such a constitution. Namely, the present invention can be suitably applied to a case of executing other method such as the CVD method for simultaneously supplying the first source gas and the second source gas onto the wafer 200. Further, the present invention is not limited to a case of supplying two kinds of gases onto the wafer 200, and can be suitably applied to a case that three kinds or more gases are supplied onto the wafer 200.

### Preferred Aspects of the Present Invention

Preferred aspects of the present invention will be additionally described hereinafter.

According to an aspect of the present invention, there is provided a substrate processing apparatus, including:

an inner tube in which a substrate is stored;

an outer tube surrounding the inner tube;

a gas nozzle disposed in the inner tube;

a gas ejection hole opened on the gas nozzle;

a gas supply unit supplying gas into the inner tube through the gas nozzle;

one or more exhaust holes opened on a side wall of the inner tube;

an exhaust unit exhausting a space between the outer tube and the inner tube and generating a gas flow in the inner tube toward the gas exhaust hole from the gas ejection hole,

wherein the side wall of the inner tube is constituted, so that a distance between an outer edge of the substrate and the gas exhaust hole is set to be longer than a distance between the outer edge of the substrate and the gas ejection hole.

Preferably, a plurality of substrates are stored in the inner tube in a state of being stacked in a horizontal posture;

the gas nozzles are disposed (extended) along a direction of stacking the substrates;

a plurality of gas ejection holes are opened along the direction of stacking the substrates; and

one or more exhaust holes are opened at positions facing the gas ejection holes across the substrates.

Preferably, each gas exhaust hole has a hole shape, and is opened at a position corresponding to each of the plurality of substrates.

Preferably, one or more gas exhaust holes are formed into a slit shape.

Preferably, a preliminary chamber protruded outward of the inner tube in a radial direction from the side wall of the inner tube is provided on the side wall of the inner tube;

the gas nozzles are disposed in the preliminary chamber; and

the gas ejection holes are opened at positions protruded outward of the inner tube in a radial direction from the side wall of the inner tube.

Preferably, the controller is provided controlling the gas supply unit and the exhaust unit,

wherein the controller controls the gas supply unit and the exhaust unit, so that a pressure in the inner tube is set to be 10 Pa or more and 700 Pa or less, when gas is supplied into the inner tube.

According to other aspect of the present invention, there is provided a substrate processing apparatus, including:

an inner tube in which a substrate is stored;

an outer tube surrounding the inner tube;

a plurality of a gas nozzle disposed in the inner tube;

gas ejection holes opened on the plurality of gas nozzles respectively;

a gas supply unit supplying gas into the inner tube through the plurality of gas nozzles;

a gas exhaust part provided on a side wall of the inner tube and at a position facing the plurality of gas nozzles across the substrates;

one or more gas exhaust holes opened on the side wall of the gas exhaust part; and

an exhaust unit exhausting a space between the outer tube and the inner tube and generating a gas flow in the inner tube toward the gas exhaust hole from the gas ejection hole,

wherein the side wall of the gas exhaust part is constituted, so that a distance between an outer edge of the substrate and the gas exhaust hole is set to be longer than a distance between the outer edge of the substrate and the gas ejection hole.

Preferably, the side wall of the gas exhaust part is constituted, so that a width of the side wall of the gas exhaust part is set to be larger than a width between gas nozzles of both ends in the plurality of gas nozzles.

Preferably, the gas exhaust part is provided so as to protrude outward of the inner tube in a radial direction from the side wall of the inner tube; and

one or more gas exhaust holes are opened at positions protruded outward of the inner tube in a radial direction from the side wall of the inner tube.

According to other aspect of the present invention, there is provided a substrate processing apparatus, including:

an inner tube in which a plurality of substrates are stored in a state of being stacked in a horizontal posture;

an outer tube surrounding the inner tube;

a first gas nozzle and a second gas nozzle disposed respectively along a direction of stacking the substrates in the inner tube;

a plurality of gas ejection holes opened on each of the first gas nozzle and the second gas nozzle, along the direction of stacking the substrates;

a gas supply unit supplying a first source gas into the inner tube through the first gas nozzle, and supplying a second source gas into the inner tube through the second gas nozzle;

gas exhaust holes opened on the side wall of the inner tube, at positions facing the gas ejection holes across the substrates;

an exhaust unit exhausting a space between the outer tube and the inner tube and generating a gas flow in the inner tube toward the gas exhaust hole from the gas ejection hole; and

a controller controlling the gas supply unit and the exhaust unit so as to alternately supply at least two kinds of gases into the inner tube without mixing them with each other,

wherein the side wall of the inner tube is constituted, so that a distance between an outer edge of the substrate and the gas exhaust hole is set to be longer than a distance between the outer edge of the substrate and the gas ejection hole.

Preferably, any one of a Zr oxide film, an Hf oxide film, an Si oxide film, an Al oxide film, a Ta oxide film, a Ti oxide film, an Ru oxide film, an Ir oxide film, an Si nitride film, an Al nitride film, a Ti nitride film, and a GeSbTe film is formed on the substrates.

Preferably, the first source gas is a gas obtained by vaporizing an organic compound or chloride containing any one of Si atom, Hf atom, Zr atom, Al atom, Ta atom, Ti atom, Ru atom, Ir atom, Ge atom, Sb atom, and Te atom.

Preferably, the second source gas is an oxidant agent or a nitriding agent.

Preferably, the controller controls the gas supply unit and the exhaust unit, so that a pressure in the inner tube is 10 Pa or more and 700 Pa or less, when the first source gas is supplied into the inner tube; and

controls the gas supply unit and the exhaust unit so that the pressure in the inner tube is 10 Pa or more and 300 Pa or less, when the second source gas is supplied into the inner tube.

Preferably, the controller controls the gas supply unit and the exhaust unit so that the pressure in the inner tube is 250 Pa when the first source gas is supplied into the inner tube, and controls the gas supply unit and the exhaust unit so that the pressure in the inner tube is 100 Pa when the second source gas is supplied into the inner tube.

According to other aspect of the present invention, there is provided a substrate processing apparatus, including:

an inner tube in which substrates are contained;

an outer tube surrounding the inner tube;

a gas nozzle disposed in the inner tube;

a gas ejection hole opened on the gas nozzle;

a gas supply unit supplying gas into the inner tube through the gas nozzle;

one or more exhaust holes opened on a side wall of the inner tube, at positions facing the gas nozzles across the substrates; and

an exhaust unit exhausting a space between the outer tube and the inner tube and generating a gas flow in the inner tube toward the gas exhaust hole from the gas ejection hole,

wherein the side wall of the inner tube is constituted, so that a distance between an outer edge of the substrate and the gas exhaust hole is set to be longer than a distance between the side wall of the inner tube (second part), on which the gas exhaust hole is not opened, and an outer edge of the substrate.

Preferably, the side wall of the inner tube is constituted, so that the distance between the side wall (first part) of the inner tube, on which the gas exhaust hole is opened, and the outer edge of the substrate is set to be longer than the distance between the side wall (second part) of the inner tube on which the gas exhaust hole is not opened and the outer edge of the substrate.

Preferably, the side wall of the inner tube is constituted, so that a curvature radius of the side wall (first part) of the inner tube on which the gas exhaust holes are opened, is set to be smaller than the curvature radius of the side wall (second part) of the inner tube on which the gas exhaust holes are not opened.

Preferably, the side wall of the inner tube is constituted, so that the side wall (first part) of the inner tube on which the gas exhaust holes are opened, is set to be protruded outward of the inner tube in a radial direction from the side wall (second part) of the inner tube on which the gas exhaust holes are not opened.

According to other aspect of the present invention, there is provided a substrate processing apparatus, including:

an inner tube in which a plurality of substrates are stored in a state of being stacked in a horizontal posture;

an outer tube surrounding the inner tube;

a first gas nozzle and a second gas nozzle disposed respectively in the inner tube along a direction of stacking the substrates;

a plurality of gas ejection holes opened respectively on the first gas nozzle and the second gas nozzle in the direction of stacking the substrates;

a gas supply unit supplying a first source gas into the inner tube through the first gas nozzle, and supplying a second source gas into the inner tube through the second gas nozzle;

one or more exhaust holes opened on a side wall of the inner tube, at positions facing the gas ejection holes across the substrates;

an exhaust unit exhausting a space between the outer tube and the inner tube and generating a gas flow in the inner tube toward the gas exhaust hole from the gas ejection hole; and

a controller controlling the gas supply unit and the exhaust unit so as to alternately supply at least two kinds of gases into the inner tube without mixing them with each other,

wherein a distance between an outer edge of the substrate and the gas exhaust hole is set to be longer than a distance between the side wall (second part) of the inner tube on which the gas exhaust hole is not opened, and the outer edge of the substrate.

Preferably, the side wall of the inner tube is constituted, so that the distance between the side wall (first part) on which the gas exhaust hole is opened, is set to be longer than the distance between the side wall (second part) of the inner tube on which the gas exhaust hole is not opened and the outer edge of the substrate.

Preferably, the side wall of the inner tube is constituted, so that a curvature radius of the side wall (first part) of the inner tube on which the gas exhaust holes are opened, is set to be smaller than the curvature radius of the side wall (second part) of the inner tube on which the gas exhaust holes are not opened.

Preferably, the side wall of the inner tube is constituted, so that the side wall (first part) of the inner tube on which the gas exhaust holes are opened is set to be protruded outward of the inner tube in a radial direction from the side wall (second part) of the inner tube on which the gas exhaust holes are not opened.

According to other aspect of the present invention, there is provided a substrate processing apparatus, which is the substrate processing apparatus for forming a prescribed thin film on a substrate surface, by alternately repeatedly supplying at least two kinds of source gases onto the substrate surface prescribed number of times, so as not to mix them with each other, said substrate processing apparatus including:

a process tube constituted of an inner tube in which a plurality of substrates are stored in a state of being stacked and an outer tube surrounding this inner tube;

a gas supply unit supplying gas into the inner tube; and

an exhaust unit exhausting an inside of the process tube,

wherein the gas supply unit has at least a first gas nozzle supplying a first source gas and a second gas nozzle supplying a second source gas, in the inner tube in such a manner as extending in a stacking direction of the substrates;

a plurality of gas ejection holes are opened on the first gas nozzle and the second gas nozzle respectively in a longitudinal direction;

gas exhaust holes are opened on a side wall of the inner tube, at positions facing the gas ejection holes; and

at least a part where the gas exhaust holes are opened, has a swelling.

What is claimed is:

1. A substrate processing apparatus, comprising:
an inner tube in which a substrate is stored;
an outer tube surrounding the inner tube;
a gas nozzle disposed in the inner tube;
a gas ejection hole opened on the gas nozzle;
a gas supply unit supplying gas into the inner tube through the gas nozzle;
one or more exhaust holes opened on a side wall of the inner tube; and
an exhaust unit exhausting a space between the outer tube and the inner tube, and generating a gas flow in the inner tube toward the gas exhaust hole from the gas ejection hole,
wherein the side wall of the inner tube is constituted so that a distance between an outer edge of the substrate and the gas exhaust hole is set to be longer than a distance between the outer edge of the substrate and the gas ejection hole.

2. The substrate processing apparatus according to claim 1, comprising:
a controller controlling the gas supply unit and the exhaust unit,
wherein the controller controls the gas supply unit and the exhaust unit, so that a pressure in the inner tube is 10 Pa or more and 700 Pa or less, when gas is supplied into the inner tube.

3. The substrate processing apparatus according to claim 1, wherein
a plurality of substrates are stored in the inner tube in a state of being stacked in a horizontal posture;
the gas nozzle is disposed along a direction of stacking the substrates;
a plurality of gas ejection holes are opened in the direction of stacking the substrates; and
one or more exhaust holes are opened at positions facing the gas ejection holes across the substrates.

4. The substrate processing apparatus according to claim 1, wherein one or more gas exhaust holes are formed into a slit shape.

5. A substrate processing apparatus, comprising:
an inner tube in which a substrate is stored;
an outer tube surrounding the inner tube;
a plurality of a gas nozzle disposed in the inner tube;
gas ejection holes opened respectively on the plurality of gas nozzles;
a gas supply unit supplying gas into the inner tube through the plurality of gas nozzles;
a gas exhaust part provided on a side wall of the inner tube, at positions facing the plurality of gas nozzles across the substrates;
one or more gas exhaust holes opened on the side wall of the gas exhaust part; and
an exhaust unit exhausting a space between the outer tube and the inner tube and generating a gas flow in the inner tube toward the gas exhaust hole from the gas ejection hole,
wherein a distance between an outer edge of the substrate and the gas exhaust hole is set to be longer than a distance between the outer edge of the substrate and the gas ejection hole.

6. The substrate processing apparatus according to claim 5, wherein the side wall of the gas exhaust part is constituted, so that a width of the side wall of the gas exhaust part is set to be larger than a width between gas nozzles on both ends of the plurality of gas nozzles.

7. The substrate processing apparatus according to claim 5, wherein
the gas exhaust part is provided so as to protrude outward of the inner tube in a radial direction from the side wall of the inner tube; and
one or more gas exhaust holes are opened at positions protruded outward of the inner tube in the radial direction from the side wall of the inner tube.

8. The substrate processing apparatus, comprising:
an inner tube in which a plurality of substrates are stored in a state of being stacked in a horizontal posture;
an outer tube surrounding the inner tube;
a first gas nozzle and a second gas nozzle disposed respectively along a direction of stacking the substrates in the inner tube;
a plurality of gas ejection holes opened respectively on the first gas nozzle and the second gas nozzle in the direction of stacking the substrates;
a gas supply unit supplying a first source gas into the inner tube through the first gas nozzle, and supplying a second source gas into the inner tube through the second gas nozzle;
one or more exhaust holes opened on a side wall of the inner tube, at positions facing the gas ejection holes across the substrates;
an exhaust unit exhausting a space between the outer tube and the inner tube and generating a gas flow in the inner tube toward the gas exhaust holes form the gas ejection holes; and
a controller controlling the gas supply unit and the exhaust unit so as to alternately supply at least two kinds of gases into the inner tube without mixing them with each other,
wherein the side wall of the inner tube is constituted, so that a distance between an outer edge of the substrate and the gas exhaust hole is set to be longer than a distance between the outer edge of the substrate and the gas ejection hole.

9. The substrate processing apparatus according to claim 8, wherein
the controller controls the gas supply unit and the exhaust unit, so that a pressure in the inner tube is 10 Pa or more and 700 Pa or less, when the first source gas is supplied into the inner tube; and
controls the gas supply unit and the exhaust unit, so that the pressure in the inner tube is 10 Pa or more and 300 Pa or less, when the second source gas is supplied into the inner tube.

10. The substrate processing apparatus according to claim 8, wherein
the controller controls the gas supply unit and the exhaust unit, so that a pressure in the inner tube is 250 Pa, when the first source gas is supplied into the inner tube; and
controls the gas supply unit and the exhaust unit, so that the pressure in the inner tube is 100 Pa, when the second source gas is supplied into the inner tube.
